(19) United States
(12) Patent Application Publication
(10) Pub. No.: US 2024/0369422 A1
(43) Pub. Date: Nov. 7, 2024

(54) Ceramic Composite Thermocouples for High Temperature Applications

(71) Applicant: West Virginia University Board of Governors on Behalf of West Virginia University, Morgantown, WV (US)

(72) Inventors: Edward M. Sabolsky, Morgantown, WV (US); Javier A. Mena, Morgantown, WV (US)

(73) Assignee: West Virginia University Board of Governors on Behalf of West Virginia University, Morgantown, WV (US)

(21) Appl. No.: 18/656,303

(22) Filed: May 6, 2024

Related U.S. Application Data
(60) Provisional application No. 63/500,261, filed on May 4, 2023.

(51) Int. Cl. G01K 7/02; C04B 28/06; C04B 41/48; C04B 41/50; C04B 41/52; C04B 41/63; C04B 41/65; C04B 41/71

(52) U.S. Cl. CPC G01K 7/028; C04B 28/06; C04B 41/4873; C04B 41/5033; C04B 41/522; C04B 41/63; C04B 41/65; C04B 41/71

(57) ABSTRACT

In one aspect, the disclosure relates to a thermocouple device fabricated from a composite mixture of lanthanum chromite and refractory oxide materials optimized for high temperature applications. The thermocouple can be manufactured as a monolithic entity or seamlessly incorporated into a manufactured article while the article is being fabricated. In another aspect, a plurality of discrete layers of the composite mixture can be applied to form the thermocouple, or the composite mixture can be continuously graded to achieve desired performance properties. In an alternative aspect, the disclosed thermocouple can be a low-cost replacement for solid-state thermocouples reliant on precious metal compositions. In a further aspect, the disclosure relates to methods of manufacturing a composite ceramic oxide thermocouple using a direct ink-writing or tape-casting process. This abstract is intended as a scanning tool for purposes of searching in the art and is not intended to be limiting of the present disclosure.

### CROSS REFERENCE TO RELATED APPLICATIONS

This application claims the benefit of U.S. provisional application entitled “Ceramic Composite High Temperature Thermocouples and Methods Thereof” having Ser. No. 63/500,261, filed May 4, 2023, which is hereby incorporated by reference in its entirety.

### STATEMENT REGARDING FEDERALLY SPONSORED RESEARCH OR DEVELOPMENT

This invention was made with government support under contract no. DE-FE0031825 awarded by the U.S. Department of Energy. The Government has certain rights in the invention.

### FIELD

This invention relates generally to ceramic thermocouples designed for harsh environmental conditions. More specifically, this disclosure relates to ceramic composite thermocouples designed to provide reliable, accurate, long-term operation in environments greater than 1100° C.

### BACKGROUND

An industrial challenge exists to accurately maintain and/or monitor the temperature of harsh environments that are greater than 1100° C. Typical industries in this application space include energy generation, metal/glass and alloy manufacturing, coal gasification, high-temperature turbines, engine health and operational monitoring, among others. Thermocouple devices can be an effective option for temperature sensing due to their ability to measure a wide spectrum of temperatures. However, most thermocouple devices applied to harsh environmental conditions have material and/or design deficiencies not well-suited to collectively achieve long-term durability and chemical stability, measurement accuracy, repeatability, and sensitivity, while also maintaining a low production cost. These inadequacies are often the result of one or more of the following issues: low material melting temperature, undesirable oxidation or chemical reactions, or thermomechanical material property incompatibilities or inconsistencies with substrate materials or environmental surroundings (e.g. gaseous atmospheres).

### SUMMARY

In accordance with the purpose(s) of the disclosure, as embodied and broadly described herein, the disclosure, in one aspect, relates to a thermocouple device fabricated from a composite mixture of undoped and/or doped lanthanum chromite (LaCrO₃) (“thermoelectric”) materials and refractory oxide (“insulating”) materials, which are electrically-insulating, for high temperature applications. Each leg of the thermocouple can comprise a different composition with different intrinsic Seebeck coefficients in order generate a measurable thermoelectric voltage while in operation. The thermocouple can be fabricated as a monolithic structure or monolithic entity or as an embedded thermocouple such that a core thermoelectric material can be embedded within a partial to fully dense ceramic matrix with high chemical and thermomechanical stability with its surroundings. In another aspect, a plurality of discrete layers of the composite mixture can be applied to each leg of the thermocouple ranging from 100% to near 0% LaCrO₃ (i.e., nearly 100% refractory oxide). In another aspect, the composite mixture can be continuously graded between 100% LaCrO₃ to near 0% LaCrO₃ (i.e., nearly 100% refractory oxide).

The disclosed thermocouple can be a relatively low-cost market replacement for solid-state thermocouples currently fabricated using precious metal compositions such as platinum (Pt), particularly as precious metal costs continue to rise over time. The disclosed thermocouple also enjoys extended longevity while operating in oxygen environments over 1100° C. compared to precious metal-based thermocouples.

In an additional aspect, the disclosure relates to methods of manufacturing a high-temperature composite ceramic oxide thermocouple using various processes. The composite mixture can be deposited by direct ink-writing, tape-casting, or similar methods on a sacrificial substrate wherein the substrate disintegrates and can be removed from the thermocouple during high-temperature treatment to densify the structure. Thermocouple sensor preforms can be manufactured to be easily incorporated into casts, molds, and other mechanisms used in the production of refractory articles to create temperature sensing articles.

Other systems, methods, features, and advantages of the present disclosure will be or become apparent to one with ordinary skill in the art upon examination of the following drawings and detailed description. It is intended that all such additional systems, methods, features, and advantages be included within this description, and be protected by the accompanying claims. In addition, all optional and preferred features and modifications of the described embodiments are usable in all aspects of the disclosure taught herein. Furthermore, the individual features of the independent claims, as well as all optional and preferred features and modifications of the described embodiments are combined and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a representative photograph of a thick-film thermocouple comprised of strontium-(Sr)-doped LaCrO₃ (LSC20) and undoped LaCrO₃ (LC) non-composite legs printed onto the surface of an alumina substrate. Chromium (Cr) can be deposited and discolored via diffusion and evaporation onto the white alumina substrate during processing and operation at high temperature in ambient air.

FIG. 2 is a representative line drawing of an example thermocouple device comprised of one inner layer in contact with an outer layer.

FIG. 3 is a representative line drawing of an example ceramic composite thermocouple device comprised of a plurality of ceramic composite inner layers in contact with a refractory oxide outer layer.

FIG. 4 is a representative line drawing of an example ceramic composite thermocouple device with one inner layer and one outer layer. The one inner layer can be comprised of a first leg comprised of an undoped LaCrO₃—Al₂0₃ [95-5] composite mixture and a second leg comprised of a calcium (Ca)-doped or La_{0.7}Ca_{0.3}CrO₃—Al₂0₃ [95-5] composite mixture. The outer layer can be comprised of a high alumina cement.

FIGS. 5A-5B are example representations of the cross-section of a composite material wherein the A-Phase is a thermoelectric material, and the B-Phase is an insulating material. FIG. 5A shows a 3-0 composite material and FIG. 5B shows a 3-3 composite material.

FIGS. 6A-6B are representative scanning electron microscopy (SEM) photographs of a 3-3 composite material composed of LaCrO₃—Al₂O₃ [70-30]. FIG. 6A shows SEM secondary electrons and FIG. 6B shows backscattered electrons where light grey areas indicate thermoelectric materials and dark grey areas indicate insulating materials and porosity.

FIG. 7 is a representative line drawing of a 2-D cross-sectional example representation of a composite thermocouple's macroscopic architecture comprised of multiple levels or layers of 3-0, 3-3, and 0-3 composite configurations from top to bottom, respectively. This illustration constitutes one half of the required architecture shown for an operable thermocouple, where the full symmetrical architecture can be illustrated with a mirror plane at the top of the figure.

FIG. 8 is a line drawing of a 2-D cross-sectional example representation of a thermocouple's macroscopic architecture composed of multiple levels or n layers of 3-0, 3-3, and 0-3 composite mixture configurations from an inner most layer to an outer most layer. Layer 1 can be located at the center of a concentric circular structure and each subsequent Layer can be added outward in the radial direction.

FIG. 9 is a representative line drawing of a six-layer ceramic composite thermocouple device described in Example 1 with layer definitions provided in Table 2.

FIG. 10 is a flow chart describing an example preparation of a composite conductive material ink comprising a composite mixture of LaCrO₃ (LC) and aluminum oxide (Al₂O₃).

FIG. 11 is a flow chart describing an example preparation of a refractory oxide ink comprising an aluminum oxide.

FIG. 12 is a flow chart describing an example preparation of an embedded thermocouple within a refractory brick.

FIG. 13 are representative SEM photographs of Layers 1 through 3 of the six-layer ceramic composite thermocouple described in Example 1 with layer definitions provided in Table 2.

FIG. 14 is representative measurement data of thermoelectric voltage as a function of temperature measurement data of the six-layer ceramic composite thermocouple described in Example 1 with layer definitions provided in Table 2.

FIG. 15 is a representative line drawing of a six-layer ceramic composite thermocouple device described in Example 2 provided in Table 4.

FIG. 16 are representative SEM photographs of Layers 1 through 3 of the six-layer ceramic composite thermocouple described in Example 2 with layer definitions provided in Table 4.

FIG. 17 is representative measurement data of thermoelectric voltage as a function of temperature of the six-layer ceramic composite thermocouple described in Example 2 with layer definitions provided in Table 4.

FIGS. 18A-18D are representative example SEM photographs of cross-sections of two printed thick-film thermocouple legs on an alumina substrate after sintering at 1500° C. for 2 hrs at two different magnification levels. FIG. 18A and FIG. 18B show a non-composite, undoped LCC30 non-composite thick-film. FIG. 18C and FIG. 18D show a LCC30-Al₂O₃ composite thick-film.

FIG. 19 shows representative example measurement data of the temperature dependence of the electrical conductivity of various LCC30-Al₂O₃ composites under atmospheric air conditions for a range of LCC30:Al₂O₃ volumetric ratios.

FIGS. 20A-20F are representative example backscattered SEM photographs of LCC30-Al₂O₃ composites for a range of LCC30:Al₂O₃ volumetric ratios after sintering at 1500° C. for 2 hrs. FIG. 20A and FIG. 20D show LCC30 and Al₂O₃ [70-30], respectively. FIG. 20B and FIG. 20E show LCC30 and Al₂O₃ [80-20], respectively. FIG. 20C and FIG. 20F show LCC30 and Al₂O₃ [90-10], respectively.

FIG. 21 shows a representative example particle size distribution for LCC30 and aluminum oxides as a function of volumetric percentage content for the different composite formulations used in thermocouple device fabrication (e.g., LCC 90% v/v denotes 90% of the volume content is LCC30).

FIG. 22 is representative example measurement data of thermoelectric voltage as a function of temperature difference measurement data for a LCC30-Al₂O₃//LC-Al₂O₃ ceramic composite thermocouple device for a range of LCC30:Al₂O₃ volumetric ratios.

FIGS. 23A-23D show exemplary steps to fabricate stencil-printed thermocouples. FIG. 23A illustrates example thermocouple pattern designs and dimensions. FIG. 23B shows an initial step of printing a first or left leg using 3-0 LC-Al₂O₃ [95-5] ink wherein the second or right leg is covered up. FIG. 23C shows a similar procedure carried out for the second leg using 3-0 LCC20-Al2O3 [95-5] ink after the first leg can dry for about 8 hrs and be covered up. FIG. 23D shows both the left and right legs of the stencil-printed thermocouples cut out of a dissolvable filter paper acting as a sacrificial substrate, and then embedded into a refractory cement.

FIGS. 24A-24D show exemplary thermocouple stencils. FIG. 24A shows photographs of plastic stencils cut in series for multiple thermocouple printing iterations. FIG. 24B shows the first or left leg of a thermocouple stencil being prepared for printing with 3-0 LC-Al₂O₃ [95-5] ink with the second leg or right leg covered. FIG. 24C an example final printed first leg of a thermocouple 3-0 LC-Al₂O₃ [95-5] ink. FIG. 24D shows a side view of thermocouples printed in series by stencils.

FIG. 25 is a flow chart describing exemplary steps to produce an embedded sensor structure or temperature sensing article by casting a thermocouple sensor preform within a refractory mold to form a monolith structure.

FIGS. 26A-26B show exemplary measurement data on stenciled thermocouples fabricated with 350-μm stencils into refractory cement. FIG. 26A shows thermoelectric voltage and isothermal dependence as a function of time for two embedded thermocouples. FIG. 26B shows the temperature dependence among the thermoelectric voltage of three different embedded thermocouples fabricated with 350-μm stencils.

FIGS. 27A-27B show exemplary measurement data measured thermoelectric voltage as a function of time on embedded thermocouple into refractory articles. FIG. 27A shows tests results wherein the sacrificial substrate used can be dissolvable paper and FIG. 27B shows test results wherein the sacrificial substrate used can be coarse filter paper.

### DETAILED DESCRIPTION

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used in the specification and the appended claims, the singular forms “a,” “an” and “the” include plural referents unless the context clearly dictates otherwise. Thus, for example, reference to “a metal,” “a metal oxide,” or “an oxidizing agent,” including, but not limited to, mixtures or combinations of two or more such metals, metal oxides, or oxidizing agents, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

Unless otherwise specified, temperatures referred to herein are based on atmospheric pressure (i.e. one atmosphere).

As used herein, the term “high alumina cement” can be a mixture comprising multiple solid oxides, wherein aluminum oxide (Al₂O₃) makes up the majority solid constituent typically in a volumetric proportion greater than 90%. The following oxides typically comprise less than 10% of the solid oxide mixture: CaO₂, SiO₂, NaO₂, and KO₃. Other phases such as Al₂CaO₄ and H₂CaO₂ can be minorly present as well within a high alumina cement composition.

As used herein, the term “monolithic structure” or “monolithic entity” can be defined as a construction or component formed by a single, continuous material such that the structure is created as a single solid piece rather than being composed of separately assembled parts.

Disclosed herein are various embodiments of thermocouple devices developed for accurate temperature monitoring in harsh environments along with their respective methods of preparation, utilizing lanthanum chromite (LaCrO₃)-based perovskite ceramics in combination with refractory oxides, for example aluminum oxide (Al₂O₃).

The two electrodes or legs of the thermocouple devices can comprise composite mixtures of undoped and/or doped LaCrO₃ (“thermoelectric”) materials and refractory oxides (“insulating”) materials to form a ceramic composite. The thermoelectric and insulating materials can be dense or porous, single or multiphase solid material wherein porosity can be considered an additional phase. The constituents that make up the composite mixtures can comprise at least one inner layer or a plurality of inner layers to produce various configurations of electrical connectivity, restricting unwanted microstructural changes and instability during thermocouple operation. This is important for the interaction of the thermoelectric components within various gaseous environments and thermomechanical instability during thermal cycling.

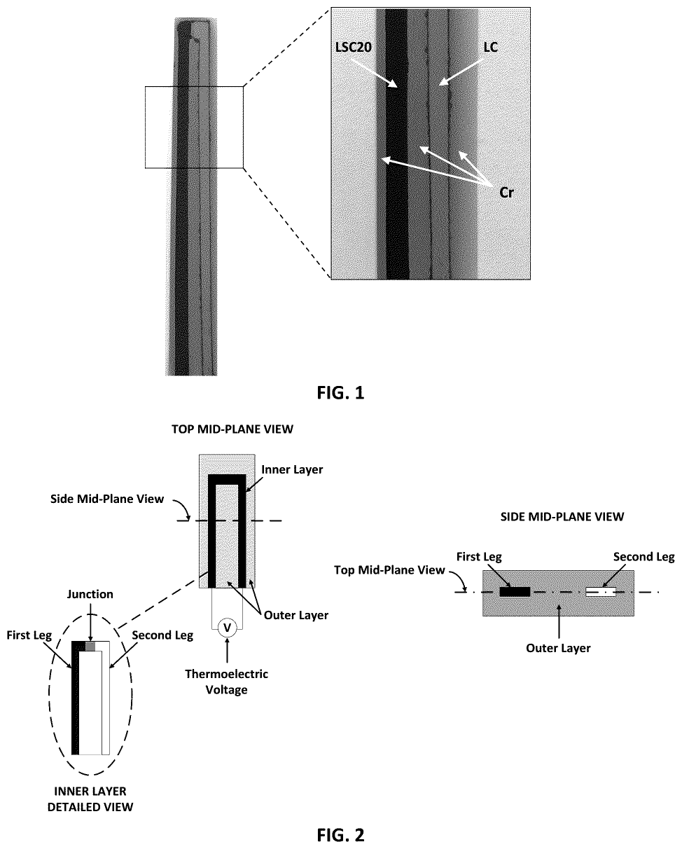

For example, FIG. 1 shows a photograph of a (non-ceramic composite) thick-film LaCrO₃ thermocouple printed onto the surface of an alumina substrate where chromium (Cr)-based vapor can be deposited and discolored the white alumina substrate during processing and operation at high-temperature in ambient air (relative humidity of approximately 30%). Upon cooling, a portion of the Cr redeposited onto the surface of the substrate. This process can dynamically continue while the thermocouple is in operation at elevated temperature. The chemistry and microstructure altered the thermoelectric properties and associated response of the thermocouple over time. This also led to signal drift which made the thermocouple perform inconsistently.

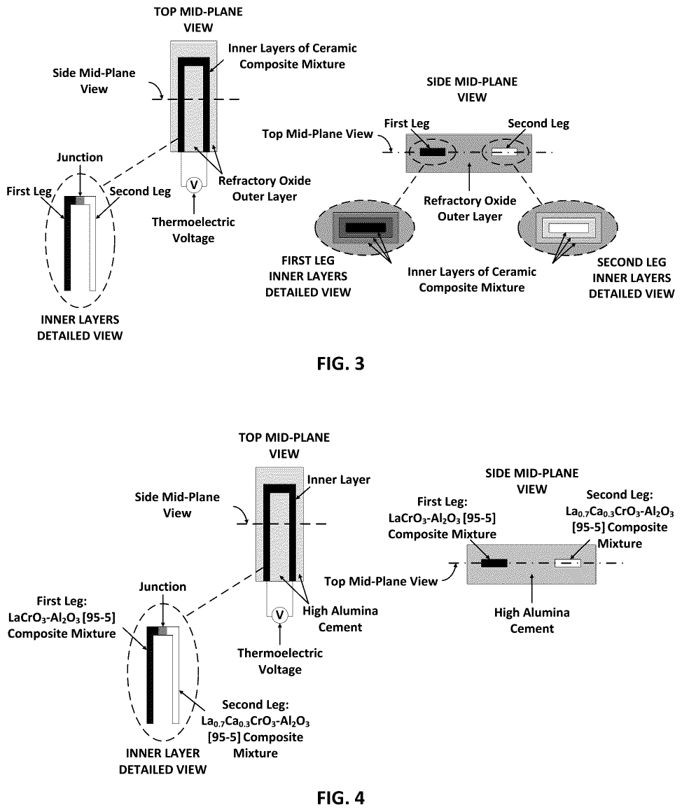

The use of a LaCrO₃ material in conjunction with a refractory oxide to form a composite mixture within a thermocouple can benefit from the existence of a microstructure with various layers of interconnectivity for reliable, long-term high temperature application. FIG. 2 shows a line drawing of an example ceramic composite thermocouple device with one inner layer in contact with an outer layer. FIG. 3 shows a line drawing of an example ceramic composite thermocouple device with a plurality of inner layers that have a functionally graded composite mixture in contact with an outer layer. FIG. 4 shows a line drawing of an example ceramic composite thermocouple device with one inner layer in contact with an outer layer which compositional detail. The inner layer is comprised of a first leg comprised of a LaCrO₃—Al₂O₃ [95-5] (undoped lanthanum chromite-aluminum oxide with a LaCrO₃—Al₂O₃ volumetric ratio of 95:5, respectively) composite mixture and a second leg comprised of La_{0.7}Ca_{0.3}CrO₃—Al₂O₃ [95-5] (calcium-doped lanthanum chromite-aluminum oxide with a La_{0.7}Ca_{0.3}CrO₃—Al₂O₃ volumetric ratio of 95:5, respectively) composite mixture. The outer layer is comprised of a high alumina cement.

Various configurations of multiple interconnected layers containing thermoelectric material can alter the overall thermoelectric properties in addition to the chemical and thermomechanical stability of the thermocouple. As defined by R. E. Newnham et al. [1, 2] for the connectivity of electrical ceramic composites, the dimensionality of connectivity, or contact of one phase to another for a multiphase composite, can be termed with the numbers 0 (no connectivity), 1 (linear connectivity), 2 (planar connectivity), or 3 (three-dimensional connectivity). For a two-phase composite material, a 2-2 composite indicates a laminar composite of the two phases. Another example of a two-phase composite material is a 3-3 composite, which designates a three-dimensional (3-D) interconnected mixture of the two phases. A 3-3 composite can appear similar to a sponge-like structure where the solid material is connected in 3-D space, as well as 3-D connectivity of the sponge porosity or void space.

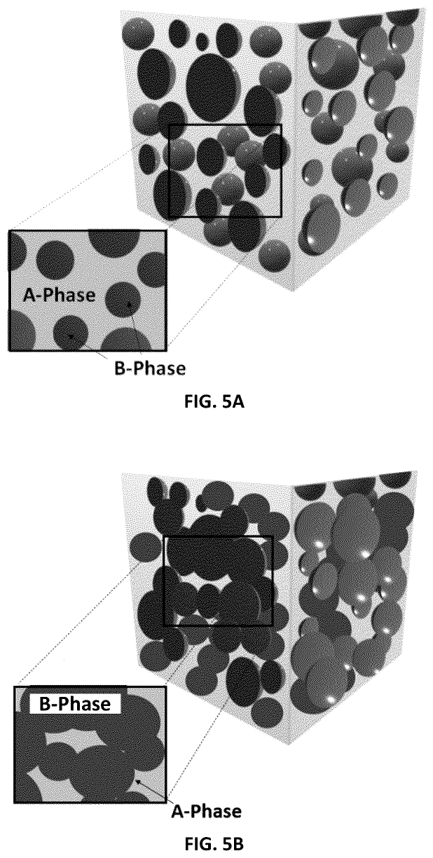

For the following representation, the first number represents the connectivity of the thermoelectric material, and the second number represents the connectivity of the insulating material. Depending on the volumetric ratio of the thermoelectric to the insulating material and the particle size ratio of each respective material phase, a 3-0 composite (at typically less than 10% by volume insulating material) (see FIG. 5A) or a 3-3 composite (at typically greater than 10% by volume insulating material) (see FIG. 5B) can be formed. An 0-3 composite designation is when the thermoelectric material particles are not interconnected nor in contact with one another.

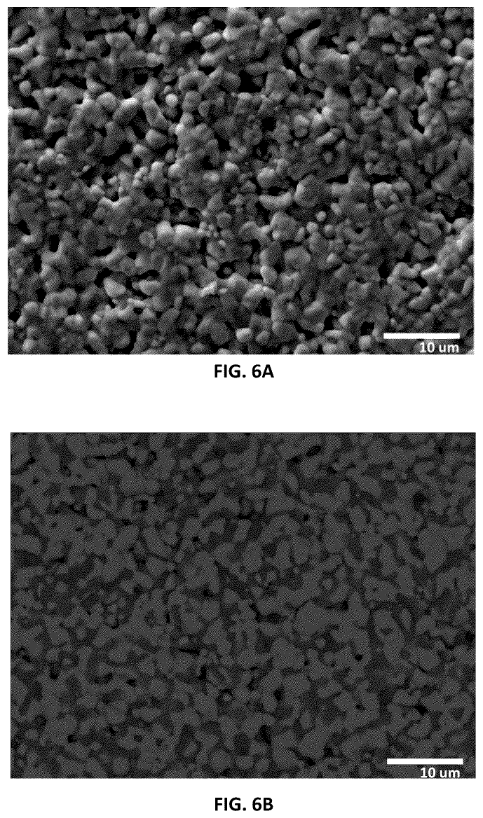

An example thermocouple design to implement this framework is the use of multiple layers of 3-3 composites comprised of thermoelectric and insulating materials. A three-layer 3-3 composite can be used to construct each leg of the thermocouple. A large quantity of layers of smaller thicknesses can alternatively be used, and approach the point of a continuous functionally-graded composite material as the quantity of layers increase. As an illustration of a 3-3 composite, FIGS. 6A-6B show a cross-sectional view of a scanning electron microscope (SEM) using a secondary electron scan (see FIG. 6A) and backscattered electron scan (see FIG. 6B) of a 3-3 composite composed of LaCrO₃—Al₂O₃ at 70 to 30% by volume, respectively.

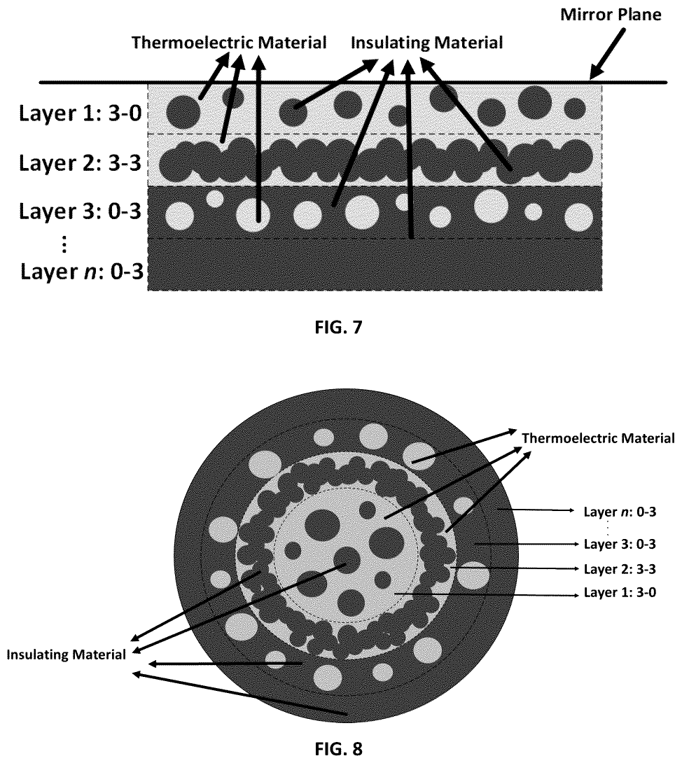

Layer 1 can comprise a core or innermost thermoelectric layer, Layer 2 can comprise an intermediate functional gradient layer, and Layer 3 can comprise an outermost layer for protection and bonding and interaction with the exterior environment. Within each layer, a 3-3 composite is defined to control the electrical properties in addition to metering the degree of chemical and thermomechanical interaction. The 3-3 composite corresponds to an interconnected, multiphase granular structure of the thermoelectric and insulating materials at different respective volumetric ratios within each layer. Layer 1 can contain a high volumetric concentration of the thermoelectric material for the 3-3 composite (or even just a 3-0 composite) compared to Layer 3 which can contain a very low (to 0% volume concentration) of the thermoelectric material (see FIG. 7). The composite microstructure can alternatively include porosity as a third phase which can include an additional third term designation, but this nomenclature is not employed herein. For simplicity, the connectivity labels for the following composites only include two numbered designations to represent the incorporation of the thermoelectric and insulating materials as single material phases only. Thermoelectric and insulating materials can also comprise multiple compositions or multiple phases of each. For example, the insulating material can comprise a mixture of combinations of Al₂O₃, Cr₂O₃, ZrO₂, and SiO₂ plus other oxides and compounds found in refractory compositions such as MgO, CaO, Fe₂O₃, P₂O₅, and so forth.

In another aspect, multi-layer microstructural composites of a laminar composite with n additional composite 2-D laminar layers can be used. The illustration shown in FIG. 7 represents half of an example layer topology since the 3-0 core thermoelectric layer (Layer 1) can be embedded within the thermocouple. The overall structure of the thermocouple is apparent with the use of a mirror plane along the top of Layer 1 wherein the overall thermoelectric sensor structure can comprise 2n total layers for n≥2, or four or more total layers. Here, Layer 1 is replicated and would be in contact with itself to comprise the core thermoelectric layer of the thermocouple. In another aspect, the overall thermoelectric structure can comprise 2n−1 total layers for n≥2, or three or more total layers. Here, a single Layer 1 application can comprise the entire core thermoelectric layer. In an alternative example, the thermocouple can be fabricated in a planar structure, as shown in FIG. 7. In another example, the thermocouple can be fabricated as a radial structure wherein Layer 1 can be located at the center of a concentric circular structure and each subsequent Layer can be added outward in the radial direction, as shown in FIG. 8. In addition, each layer can vary in dimension such that each layer can be the same thickness or different thickness. For example, the core thermoelectric layer (Layer 1) can vary from about 0.05- to 5-mm thick, and the additional (Layers 2 through n) layers can vary from about 0.05- to 300-mm in thickness apiece. The overall thermocouple can be fabricated at any length scale, only limited by the particle size of its raw materials and the number of layers and their respective thicknesses. The overall thermocouple can have length scales on the order of sub-millimeter to tens of centimeters with a rectangular or circular cross-sectional shape and on the order of 1-cm to 1-m in total length.

In one embodiment, a thermocouple device can comprise at least one inner layer embedded within an outer layer. The outer layer can comprise at least one phase of a first refractory oxide. At least one inner layer can comprise a first leg and a second leg. The first leg can comprise a first composite mixture of at least one phase of a first undoped or doped LaCrO₃ in contact with at least one phase of a second refractory oxide. The second leg can comprise a second composite mixture of at least one phase of a second undoped or doped LaCrO₃ in contact with at least one phase of a third refractory oxide. The first leg and the second leg can be in electrical contact with each other to form a junction. The first composite mixture and the second composite mixture can be different compositions such that a thermoelectric voltage can be generated between the first leg and the second leg.

In a further aspect, at least one inner layer can have a porosity of about 0 to 80%.

In a further aspect, the first composite mixture can have a porosity of about 0 to 80%.

In a further aspect, the second composite mixture can have a porosity of about 0 to 80%.

In a further aspect, at least one phase of the first refractory oxide can comprise aluminum oxide or alumina (Al₂O₃), chromium (III) oxide or chromia (Cr₂O₃), zirconium dioxide or zirconia (ZrO₂), silicon dioxide or silica (SiO₂), magnesium oxide or magnesia (MgO), calcium oxide (CaO), ferric oxide (Fe₂O₃), phosphorous pentoxide (P₂O₅), or combinations thereof.

In a further aspect, at least one phase of the second refractory oxide can comprise Al₂O₃, Cr₂O₃, ZrO₂, SiO₂, MgO, CaO, Fe₂O₃, P₂O₅, or combinations thereof.

In a further aspect, at least one phase of the third refractory oxide can compromise Al₂O₃, Cr₂O₃, ZrO₂, SiO₂, MgO, CaO, Fe₂O₃, P₂O₅, or combinations thereof.

In a further aspect, at least one phase of the first refractory oxide, at least one phase of the second refractory oxide, and at least one phase of the third refractory oxide can comprise a similar refractory oxide.

In a further aspect, at least one phase of the first refractory oxide, at least one phase of the second refractory oxide, and at least one phase of the third refractory oxide can comprise Al₂O₃, Cr₂O₃, or combinations thereof.

In a further aspect, at least one phase of the first refractory oxide, at least one phase of the second refractory oxide, and at least one phase of the third refractory oxide can comprise Al₂O₃.

In a further aspect, at least one phase of the first refractory oxide, at least one phase of the second refractory oxide, and at least one phase of the third refractory oxide can comprise Cr₂O₃.

In a further aspect, at least one phase of the first refractory oxide can comprise a high alumina cement.

In a further aspect, at least one phase of the first undoped or doped LaCrO₃ or at least one phase of the second undoped or doped LaCrO₃ can comprise a composition represented by the formula (La₁₋ₓAₓ)(Cr_{1-y}B_{y})O₃, wherein A=calcium (Ca), strontium (Sr), barium (Ba), or yttrium (Y) and B=niobium (Nb), titanium (Ti), zirconium (Zr), manganese (Mn), iron (Fe), cobalt (Co), copper (Cu), nickel (Ni), zinc (Zn), aluminum (Al), gadolinium (Gd), neodymium (Nd), or samarium (Sm), 0≤x≤0.5 and 0≤y≤0.5.

In a further aspect, at least one phase of the first undoped or doped LaCrO₃ or at least one phase of the second undoped or doped LaCrO₃ can comprise a composition represented by the formula (La₁₋ₓAₓ)CrO₃, wherein A=Ca or Sr, 0<x≤0.3.

In a further aspect, at least one phase of the first undoped or doped LaCrO₃ or at least one phase of the second undoped or doped LaCrO₃ can comprise a composition represented by the formula (La₁₋ₓAₓ)CrO₃, wherein A=Ca, 0.2≤x≤0.3.

In a further aspect, at least one phase of the first undoped or doped LaCrO₃ or at least one phase of the second undoped or doped LaCrO₃ cam comprise a composition represented by the formula (La₁₋ₓAₓ)CrO₃, wherein A=Ca, x=0.3.

In a further aspect, at least one phase of the first undoped or doped LaCrO₃ and at least one phase of the second refractory oxide can be present in the first composite mixture in a volumetric ratio ranging from about 70:30 to 99:1, respectively. At least one phase of the second undoped or doped LaCrO₃ and at least one phase of the third refractory oxide can be present in the second composite mixture in a volumetric ratio ranging from about 70:30 to 99:1, respectively.

In a further aspect, at least one phase of the first undoped or doped LaCrO₃ and at least one phase of the second refractory oxide can be present in the first composite mixture in a volumetric ratio ranging from about 90:10 to 99:1, respectively. At least one phase of the second undoped or doped LaCrO₃ and at least one phase of the third refractory oxide can be present in the second composite mixture in a volumetric ratio ranging from about 90:10 to 99:1, respectively.

In a further aspect, at least one phase of the first undoped or doped LaCrO₃ and at least one phase of the second refractory oxide can be present in the first composite mixture in a volumetric ratio ranging from about 90:10 to 95:5, respectively. At least one phase of the second undoped or doped LaCrO₃ and at least one phase of the third refractory oxide can be present in the second composite mixture in a volumetric ratio ranging from about 90:10 to 95:5, respectively.

In a further aspect, at least one phase of the first undoped or doped LaCrO₃ and at least one phase of the second refractory oxide can be present in the first composite mixture in a volumetric ratio of about 70:30, respectively. At least one phase of the second undoped or doped LaCrO₃ and at least one phase of the third refractory oxide can be present in the second composite mixture in a volumetric ratio of about 70:30, respectively.

In a further aspect, at least one phase of the first undoped or doped LaCrO₃ and at least one phase of the second refractory oxide can be present in the first composite mixture in a volumetric ratio of about 80:20, respectively. At least one phase of the second undoped or doped LaCrO₃ and at least one phase of the third refractory oxide can be present in the second composite mixture in a volumetric ratio of about 80:20, respectively.

In a further aspect, at least one phase of the first undoped or doped LaCrO₃ and at least one phase of the second refractory oxide can be present in the first composite mixture in a volumetric ratio of about 90:10, respectively. At least one phase of the second undoped or doped LaCrO₃ and at least one phase of the third refractory oxide can be present in the second composite mixture in a volumetric ratio of about 90:10, respectively.

In a further aspect, at least one phase of the first undoped or doped LaCrO₃ and at least one phase of the second refractory oxide can be present in the first composite mixture in a volumetric ratio of about 95:5, respectively. At least one phase of the second undoped or doped LaCrO₃ and at least one phase of the third refractory oxide can be present in the second composite mixture in a volumetric ratio of about 95:5, respectively.

In a further aspect, three-dimensional microstructure connectivity can be present in the first composite mixture, the second composite mixture, or combination thereof.

In a further aspect, three-dimensional microstructure connectivity can be present in the at least one phase of a first undoped or doped LaCrO₃, the at least one phase of a second undoped or doped LaCrO₃, or combination thereof.

In a further aspect, at least one phase of the first refractory oxide or at least one phase of the second refractory oxide can have no microstructure connectivity, or combination thereof.

In a further aspect, at least one phase of a first undoped LaCrO₃ and at least one phase of a second refractory oxide can be present in the first composite mixture in a volumetric ratio ranging from about 70:30 to 99:1, respectively. At least one phase of a second doped LaCrO₃ represented by the formula La_{0.7}Ca_{0.3}CrO₃ and at least one phase of a third refractory oxide can be present in the second composite mixture in a volumetric ratio ranging from about 70:30 to 99:1, respectively. At least one phase of a first refractory oxide, at least one phase of a second refractory oxide, and at least one phase of a third refractory oxide can comprises Al₂O₃, Cr2O₃, or combination thereof.

In a further aspect, at least one phase of a first undoped LaCrO₃ and at least one phase of a second refractory oxide can be present in the first composite mixture in a volumetric ratio ranging from about 70:30 to 95:5, respectively. At least one phase of a second doped LaCrO₃ represented by the formula La_{0.7}Ca_{0.3}CrO₃ and at least one phase of a third refractory oxide can be present in the second composite mixture in a volumetric ratio ranging from about 70:30 to 95:5, respectively. At least one phase of a first refractory oxide, at least one phase of a second refractory oxide, and at least one phase of a third refractory oxide can comprises Al₂O₃, Cr₂O₃, or combination thereof.

In a further aspect, at least one phase of a first undoped LaCrO₃ and at least one phase of a second refractory oxide can be present in the first composite mixture in a volumetric ratio ranging from about 90:10 to 95:5, respectively. At least one phase of a second doped LaCrO₃ represented by the formula La_{0.7}Ca_{0.3}CrO₃ and at least one phase of a third refractory oxide can be present in the second composite mixture in a volumetric ratio ranging from about 90:10 to 95:5, respectively. At least one phase of a first refractory oxide, at least one phase of a second refractory oxide, and at least one phase of a third refractory oxide can comprise Al₂O₃, Cr₂O₃, or combination thereof.

In a further aspect, at least one inner layer and the outer layer can form a monolithic structure.

In a further aspect, the thermocouple device can be a monolithic structure.

In a further aspect, at least one inner layer can comprise a plurality of inner layers. The plurality of inner layers has a functionally graded microstructure such that the volumetric ratio of refractory oxide within each layer increases from an inner most layer to the outer layer.

In a further aspect, the thermocouple device can have a stable temperature sensing range from about 100 to about 1500° C.

In a further aspect, the thermocouple device can have a stable temperature sensing range from about 20 to about 1500° C.

In a further aspect, the thermocouple device can have an effective Seebeck coefficient of about 230 to about 250 μV/K.

In another embodiment, a temperature sensing article can comprise at least one inner layer embedded within an outer layer. At least one inner layer can comprise a first leg and a second leg. The first leg can comprise a first composite mixture of an undoped or doped LaCrO₃ in contact with a refractory oxide in a volumetric ratio ranging from about 70:30 to 95:5, respectively. The second leg can comprise of a second composite mixture of an undoped of doped LaCrO₃ in contact with a refractory oxide in a volumetric ratio ranging from about 70:30 to 95:5, respectively. The first leg and the second leg can be in electrical contact with each other to form a junction. The first composite mixture and the second composite can be different compositions such that a thermoelectric voltage is generated between the first leg and the second leg. The doped LaCrO₃ can be represented by the formula La_{0.7}Ca_{0.3}CrO₃. The outer layer can comprise a refractory oxide. The refractory oxide can comprise Al₂O₃, Cr₂O₃, ZrO₂, SiO₂, MgO, CaO, Fe₂O₃, P₂O₅, or combinations thereof. The temperature sensing article can be a monolithic structure.

In an alternate embodiment, a thermocouple sensor preform can comprise a first leg, a second leg, and a sacrificial substrate. The first leg can comprise a first composite mixture of an undoped or doped LaCrO₃ in contact with a refractory oxide in a volumetric ratio ranging from about 70:30 to 95:5, respectively. The second leg can comprise a second composite mixture of an undoped or doped LaCrO3 in contact with a refractory oxide in a volumetric ratio ranging from about 70:30 to 95:5, respectively. The first leg and the second leg can be disposed on the sacrificial substrate and can be in electrical contact with each other to form a junction. The first composite mixture and the second composite mixture can be different compositions such that a thermoelectric voltage is generated between the first leg and the second leg. The doped LaCrO₃ can be represented by the formula La_{0.7}Ca_{0.3}CrO₃. The sacrificial substrate can disintegrate at a temperature lower than the sintering temperature of the first composite mixture and the second composite mixture.

In an alternate embodiment, there can be a method of making a thermocouple device, comprising the steps of:
(a) Forming a first outer layer comprising at least one phase of a first refractory oxide;
(b) Forming at least one inner layer comprising a first leg and a second leg connected at a junction;
(c) Forming a second outer layer comprising at least one phase of the first refractory oxide;
(d) Embedding the at least one inner layer between the first outer layer and the second outer layer to form a plurality of layers;
(e) Heat treating the plurality of layers to densify the plurality of layers;
   wherein the first leg can comprise a first composite mixture of at least one phase of a first undoped or doped LaCrO₃ material and at least one phase of a second refractory oxide;
   wherein the second leg can comprise a second composite mixture of at least one phase of a second undoped or doped LaCrO₃ material and at least one phase of a third refractory oxide material; and
   wherein the first composite mixture and the second composite mixture are different compositions such that a thermoelectric voltage can be generated between the first leg and the second leg.

In a further aspect, the heat-treating process can be a sintering process.

In a further aspect, the plurality of layers is sintered to about 1500° C. for at least 2 hrs.

In a further aspect, the first outer layer and the second outer layer can be formed by casting at least one phase of a first refractory oxide material and at least one phase of a second refractory oxide material, respectively, into the cavity of a mold.

In a further aspect, at least one inner layer can comprise the first leg and the second leg can be produced via tape casting.

In a further aspect, at least one inner layer can comprise the first leg and the second leg is produced via direct ink writing onto the sacrificial substrate.

In a further aspect, the sacrificial substrate can be a coarse filter paper or a dissolvable filter paper.

In a further aspect, the sacrificial substrate can be a filter paper with about 2.5 μm

In a further aspect, the sacrificial substrate can be a filter paper with about 30 to 50-μm pore size.

In a further aspect, the sacrificial substrate can be a solid film such that it disintegrates or volatizes at temperatures greater than 800° C.

Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Chemical composition formulas are referred to using acronyms followed by a number to indicate, if applicable, the doping level. For example, LCC10 refers to La_{0.9}Ca_{0.1}CrO₃, or lanthanum chromite doped with 10% calcium (calcium 0.1 mol content on the La-site of the composition). Table 1 lists example chemical composition formulas and their respective acronyms that will be referred to herein.

TABLE 1
Compositions and Related Acronyms for Fabricated
Ceramic Composite Thermocouples.

| Chemical Composition Formula | |
|---|---|
| (x or y = mol % doping level) | General Acronym |
| LaCrO₃ | LC |
| La₁₋ₓCaₓCrO₃ | LCC |

For simplicity, the composition designation of [thermoelectric percent volume−insulator percent volume] is used to identify the volumetric percentage of the composites. For example, LCC20-Al₂O₃ [90-10 or 90-10] indicates a 90% volume of LCC20 and 10% volume of Al₂O₃.

### REFERENCES

Ref. 1: Tresslera, J. F.; Alkoya, S.; Doganb, A.; Newnham, R. E. Functional composites for sensors, actuators, and transducers. Composites: Part A 30 477-482 (1999).

Ref. 2: Pilgrim S. M.; Newnham, R. E. New Composites Connectivity. Mat. Res. Bull. 21, 1447-1454 (1986).

Ref. 3: J. A. Mena, V. Mendoza-Estrada, E. M. Sabolsky, K. Sierros, K. Sabolsky, R. González-Hernández, K. S. Varadharajan Idhaiam, “Exploring the Impact of Multivalent Substitution on High-Temperature Electrical Conductivity in Doped Lanthanum Chromite Perovskites: An Experimental and Ab-initio Study,” Journal of the European Ceramic Society, 2024, ISSN 0955-2219 (DOI: 10.1016/j.jeurceramsoc.2024.04.062).

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: 6-Layer LaCrO₃-Based Ceramic Composite Thermocouple (Leg 1=LCC20-Al₂O₃ and Leg 2=LC-Al₂O₃)

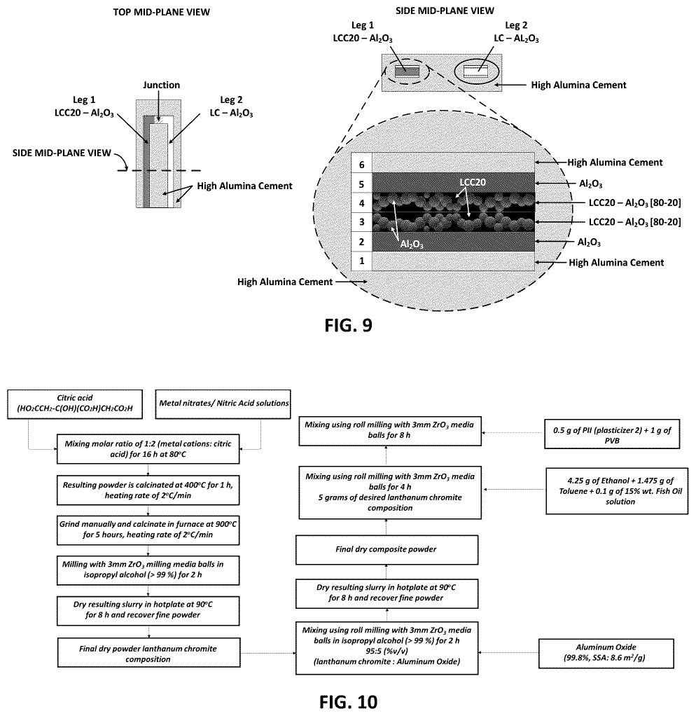

A six-layer thermocouple can be fabricated using LCC20-Al₂O₃ [80-20] and LC-Al₂O₃ [80-20] compositions as the core or inner most thermoelectric materials for Leg 1 and Leg 2, respectively. The six-layer thermocouple utilizes three layers of differing composition mirrored about the inner most layers to fabricate six total layers. The six layers from this example are listed from bottom to top in Table 2. FIG. 9 illustrates a top and side mid-plane view of this example.

TABLE 2
Example 1 Thermocouple Layer Description.

| Layer No. | Leg 1 | Leg 2 |
|---|---|---|
| 6 | 0-3 High alumina cement | 0-3 High alumina cement |
| 5 | 0-3 Al₂O₃ | 0-3 Al₂O₃ |
| 4 | 3-3 LCC20-Al₂O₃ [80-20] | 3-3 LC-Al₂O₃ [80-20] |
| 3 | 3-3 LCC20-Al₂O₃ [80-20] | 3-3 LC-Al₂O₃ [80-20] |
| 2 | 0-3 Al₂O₃ | 0-3 Al₂O₃ |
| 1 | 0-3 High alumina cement | 0-3 High alumina cement |

Undoped and Ca-doped LaCrO₃-based powders were prepared via a Pechini sol-gel method by employing citric acid (HO₂CCH₂—C(OH)(CO₂H)CH₂CO₂H) (99.9% purity) and La(NO₃)₃.6H₂O (99.9% purity), Cr(NO₃)₃.9H₂O (99.9% purity), Sr(NO₃)₂ (99.5% purity), Ca(NO₃)₂.4H₂O (99.5% purity) and Mn(NO₃)₂.4H₂O (99.0% purity) as metals sources from Sigma Aldrich, USA. The accuracy of the final metal solution concentrations were established by ICP-MS measurements. The solution amounts of metallic species for each composition (See Table 2) were weighted and mixed with citric acid in deionized water at an equivalent molar ratio of about 1:2 metal cations to citric acid. The solutions were heated to about 80° C. using a hotplate for about 16 hours to form a viscous gel that yielded a purple solid precursor. The gel can then be heat treated at about 400° C. using a furnace with a heating rate of about 1° C. per minute and then held at about 400° C. for about 1 hour to remove any remaining organic materials. Samples were pulverized manually in a mortar and calcined in a furnace at 900° C. for about 5 hours. The resulting powders were milled with isopropyl alcohol (99.5% purity) in 3-mm ZrO₃-milling media for about two hours. The milled powders were then characterized by X-ray diffraction (XRD, PANalytical X'pert PRO, Cu Kα radiation, model number PW 3040 Pro, West Virginia University). Power requirements during the operation were 45 kV and 40 mA. The divergence slit angle for the incident X-ray beam can be set to 0.5°. Scans were performed with a 0.033°/s scan rate and a 40 second step time. More detailed scans were performed using a 0.016°/s scan rate and a 400 second step time. Jade v9.6 Materials Data Inc. can be used for phase identification and pattern analysis.

The 3-3 LaCrO₃-based composite powders were then prepared. The composite consisted of 80% by volume LCC20 with 20% by volume Al₂O₃ (Al₂O₃; 99.8%, SSA: 8.6 m²/g) (volume ratio). The composite powder can be generally prepared by mixing both powders in the required volumetric ratio, alumina, zirconia milling media and isopropyl alcohol. The mixture can be left for about 2 hours on a US Stoneware 755RMV ball rolling system. After milling, the zirconia media can be strained out and the powder-alcohol mixture can be dried on a hot plate at about 90° C. for about 8 hours. FIG. 10 shows a flow chart of this process:

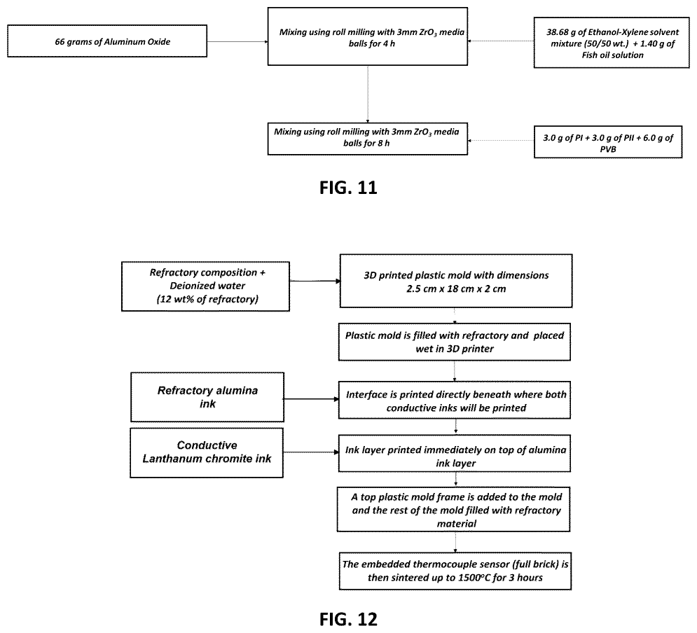

0-3 Al₂O₃ inks were prepared by mixing 66 grams of powder with about 38.7 g of an ethanol-xylene mixture (50-50% by weight) and 1.4 grams of a fish oil solution in xylene for about 4 hours on a US Stoneware 755RMV ball rolling system. Finally, 3.0 g of Plasticizer UCON50HB2000 (Polyalkylene Glycol), 3.0 g of Plasticizer S-160 (butyl benzyl phthalate) and 6.0 g of Polyvinyl butyral (PVB) were added to the previous mixture and mixed for about 8 hours on a US Stoneware 755RMV ball rolling system. The method to form the ink is shown in FIG. 11.

A three-part mold for the desired specification can be fabricated from polylactic acid (PLA) with dimensions 2.5×18×2-cm. An oil release agent can be applied to the inside of the mold pieces, and the base and middle frame were assembled for casting. The high alumina cement can be fabricated using the manufacturer's instructions (280 grams of high alumina cement mixed with 12% by weight of water). The high alumina cement can be poured into the mold to form Layer 1. While the refractory can be wet and setting, the mold can be moved to a Nordson Direct Ink Jet Printer (3-Axis EV Series Automated Fluid Dispensing Robot) to print Layer 2 and then Layer 3. The previously prepared inks were placed into printing syringes, capped, and then set aside for use. The Al₂O₃ ink (Layer 2) can be printed over Layer 1, whereby Layer 2 covered a slightly wider area than Layer 1 to be printed. The 3-3 Layer 3 composite inks (the two inks for each leg of the thermocouple to form the U-shaped thermocouple design) can be printed over Layer 2. This method can then be performed for Layer 1 through Layer 3, but in reverse for symmetry to form six total layers. Table 3 describes the printing setting for each of the direct-written layers (i.e., Layers 2 through 5). FIG. 12 displays the flow chart for the fabrication of the thermocouple described above.

TABLE 3
Example 1 Thermocouple 3-D Print Settings.

| | Pressure | Line Speed | Nozzle | Print width |
|---|---|---|---|---|
| Ink Material | (psi) | (mm) | Gauge | (mm) |
| Al₂O₃ | 5.0 | 10 | 21 | 3 |
| LC-Al₂O₃ [80-20] | 5.5 | 10 | 22 | 2 |
| LCC20-Al₂O₃ [80-20] | 5.5 | 10 | 22 | 2 |

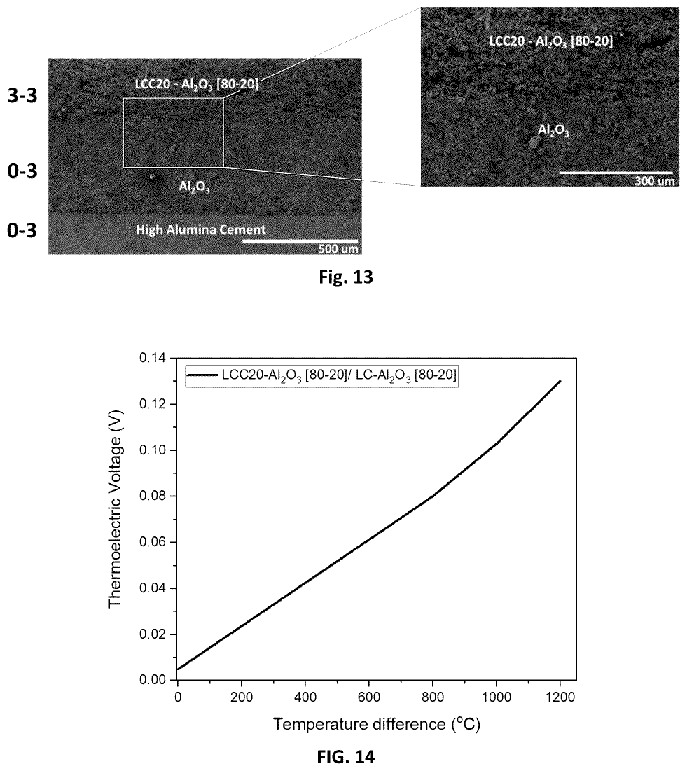

FIG. 13 shows cross-sectional SEM close-up pictures of Layers 1 through 3 of the total six-layer composite structure, i.e., high alumina cement (Layer 1), 0-3 Al₂O₃ (Layer 2), and 3-3 LCC20-Al₂O₃ [80-20] (Layer 3)

FIG. 14 shows the thermoelectrical characterization data (thermoelectric voltage versus temperature difference) for the 3-D printed embedded thermocouple. The thermoelectrical voltage is plotted as a function of the temperature difference. As seen the thermoelectric voltage is directionally proportional and correlated with temperature difference. The thermoelectric testing can be completed up to 1300° C. Therefore, the thermoelectric voltage is expected to track linearly with the plots shown for the high temperature previous measurements. This six-layer thermocouple showed a maximum voltage of 130 mV. This data provides evidence of a doped LaCrO₃-based thermocouple operating with an excellent resolution and a very high signal-to-noise ratio.

### Example 2: 6-Layer LaCrO₃-Based Ceramic Composite Thermocouple (Leg 1=LCC20-Al₂O₃ and Leg 2=LC-Al₂O₃)

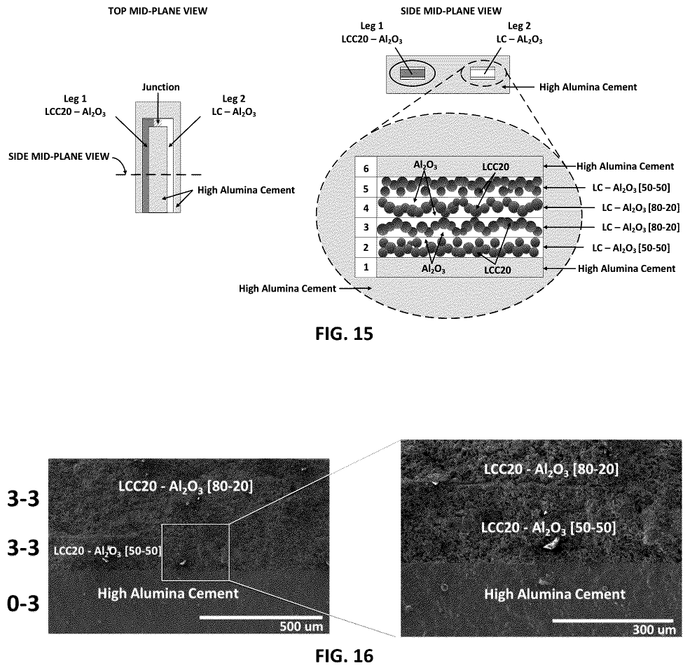

A 6-layer thermocouple can be fabricated using LCC20-Al₂O₃ [80-20] and LC-Al₂O₃ [80-20] and LCC20-Al₂O₃ [50-50] and LC-Al₂O₃ [50-50] compositions as the primary and secondary core or inner most thermoelectric materials for Leg 1 and Leg 2, respectively. The six-layer thermocouple utilized three layers of differing composition mirrored about the inner most layers to fabricate six total layers. The six layers from this example are listed from bottom to top in Table 4. FIG. 15 illustrates a top and side mid-plane view of this example.

TABLE 4
Example 2 Thermocouple Layer Description.

| Layer No. | Leg 1 | Leg 2 |
|---|---|---|
| 6 | 0-3 High alumina cement | 0-3 High alumina cement |
| 5 | 3-3 LCC20-Al₂O₃ [50-50] | 3-3 LC-Al₂O₃ [50-50] |
| 4 | 3-3 LCC20-Al₂O₃ [80-20] | 3-3 LC-Al₂O₃ [80-20] |
| 3 | 3-3 LCC20-Al₂O₃ [80-20] | 3-3 LC-Al₂O₃ [80-20] |
| 2 | 3-3 LCC20-Al₂O₃ [50-50] | 3-3 LC-Al₂O₃ [50-50] |
| 1 | 0-3 High alumina cement | 0-3 High alumina cement |

The preparation methods to produce the thermocouple in Example 2 were the same as those performed in Example 1, but with the altered compositions identified in Table 4 and FIG. 15. Table 3 describes the printing setting for each of the direct-written layers (i.e., Layer 2 through Layer 5).

TABLE 5
Example 2 Thermocouple 3-D Print Settings.

| | Pressure | Line Speed | Nozzle | Print width |
|---|---|---|---|---|
| Ink Material | (psi) | (mm) | Gauge | (mm) |
| Al₂O₃ | 5.0 | 10 | 21 | 3 |
| LC-Al₂O₃ [80-20] | 5.5 | 10 | 22 | 2 |
| LCC20-Al₂O₃ [80-20] | 5.5 | 10 | 22 | 2 |
| LC-Al₂O₃ [50-50] | 5.5 | 10 | 22 | 2 |
| LCC20-Al₂O₃ [50-50] | 5.5 | 10 | 22 | 2 |

FIG. 16 shows cross-sectional SEM close-up pictures of Layers 1 through 3 of the total six-layer composite structure, i.e. high alumina cement (Layer 1), 3-3 LCC20-Al₂O₃ [50-50] (Layer 2), and 3-3 LCC20-Al₂O₃ [80-20] (Layer 3).

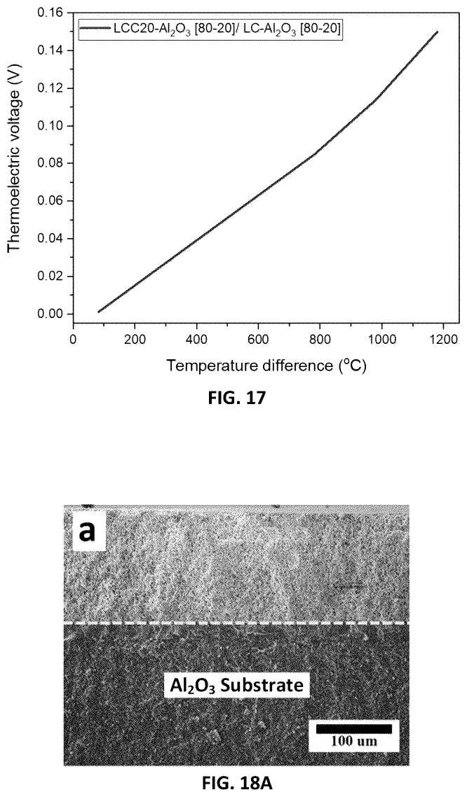

FIG. 17 shows the thermoelectrical characterization data (thermoelectric voltage versus temperature difference) for the 3-D printed embedded thermocouple. The thermoelectrical voltage is plotted as a function of the temperature difference and is directly proportional and correlated with temperature difference. The thermoelectric testing can be completed up to 1300° C.; Therefore, the thermoelectric voltage is expected to track linearly with the plots shown for the high temperature previous measurements. This six-layer thermocouple showed a maximum voltage of 150 mV. This data provides evidence of a doped LaCrO₃-based thermocouples operating with an excellent resolution and a very high signal-to-noise ratio.

### Examplary Series of LaCrO₃-Based Ceramic Composite Thermocouples Over Varied LaCrO₃—Al₂O₃ Volumetric Ratios

Doped LCC30-Al₂O₃ and undoped LC-Al₂O₃ composites were used to fabricate thick-film thermocouples by stencil printing methods. The effects of dopant concentration (within the LC composition) and the Al₂O₃ composite content on the chemical stability, microstructure, and thermoelectrical properties were examined. Chemical phase development can be characterized by utilizing X-ray diffraction (XRD), energy-dispersive X-ray spectroscopy (EDS), and X-ray photoelectron spectroscopy (XPS). The microstructure evolution can also be characterized by scanning electron microscopy (SEM).

### Example 4: Doped LaCrO₃-Based Composites Preparation Method

Strontium (Sr), calcium (Ca) and strontium/manganese (Sr/Mn) substituted or doped lanthanum chromite (La₁₋ₓSrₓCrO₃, La₁₋ₓCaₓCrO₃ and La_{0.8}Sr_{0.2}Cr₁₋ₓMnₓO₃ (0.1≤x≤0.3)) compositions were synthesized by a Pechini sol-gel method, employing citric acid (HO₂CCH₂—C(OH)(CO₂H)CH₂CO₂H) (99.9% purity) as a complexing agent and La(NO₃)₃.6H₂O (99.9% purity), Cr(NO₃)₃.9H₂O (99.0% purity), Sr(NO₃)₂ (99.5% purity), Ca(NO₃)₂ (99.5% purity) and Mn(NO₃)₂.xH₂O (99.0% purity) as the metal salt sources (all from Sigma Aldrich, USA). To simplify nomenclature, compositions are labeled as follows: LCCₓ, LSCₓ, and LSCMₓ for Ca, Sr and Sr/Mn substitution, respectively, where x indicates the percentage of molar substitution level (i.e., 0 to 30%). All metal nitrates were dissolved in deionized water, and the accuracy of the final metal concentrations can be established by an inductively coupled plasma-mass spectrometer (ICP-MSPerkin Elmer NexION 2000, USA) following the EPA Method 200.8.

The necessary solution concentration of metal species for each desired composition cam be weighed and mixed with citric acid at an equivalent molar ratio of 1:2 (metal cations: citric acid). Solutions were heated to about 80° C. until a viscous gel formed which finally yielded a purple solid precursor while slow drying. The dried gel can then then thermally treated at about 400° C. for 1 hr to remove the organic material. Samples were pulverized manually in a mortar and calcined at about 1200° C. for 3 hrs. Before the ceramic composite thick-film thermocouples were fabricated, doped LaCrO₃—Al₂O₃ composite powder mixtures were prepared. Table 6 lists the compositions. As a reminder, the following designation of [X-Y] can be used to identify the composition and volume percentage of the prepared composites. For example, LCC20-Al₂O₃ [90-10] indicates 90% by volume of LCC20 and 10% by volume of Al₂O₃. The symbol “//” represents the thermocouple junction, wherein the compositions to the left and right of “//” represent the composition of a first leg and second leg of the thermocouple, respectively. The appropriate amounts of doped LaCrO₃ powders were mixed with alumina (Al₂O₃) powder (99.8%, SSA: 8.6 m²/g, Almatis, Leetsdale, PA) and posteriorly ball-milled in a high-density polyethylene (HDPE) jar, using isopropyl alcohol and 5-mm diameter zirconia milling media (Tosoh Corporation, Japan) for 2 hrs. The final uniform powders mixtures were dried at 80° C. in a vacuum oven.

TABLE 6
Configurations and Compositions of Thermocouples Examined.

| Thermocouple | Leg 1 | Leg 2 |
|---|---|---|
| LCC30 - Al₂O₃ [90-10] // LC - Al₂O₃ [90-10] | LCC30 - Al₂O₃ [90-10] | LC - Al₂O₃ [90-10] |
| LCC30 - Al₂O₃ [80-20] // LC - Al₂O₃ [80-20] | LCC30 - Al₂O₃ [80-20] | LC - Al₂O₃ [80-20] |
| LCC30 - Al₂O₃ [70-30] // LC - Al₂O₃ [70-30] | LCC30 - Al₂O₃ [70-30] | LC - Al₂O₃ [70-30] |

*Volume percentages are represented by [X-Y] wherein X and Y correspond to the volume fraction percentage of the conductive phase and insulating refractory oxide phase, respectively.

### Example 5: Ink Formulation and Stencil Printing of Thermocouples on High-density Substrates

The doped LaCrO₃—Al₂O₃ composite ink used in the stencil printing of the thick-film thermocouples can be prepared by mixing an organic vehicle (63-2 vehicle, Johnson Matthey, USA) and the previously prepared composite powders using an ultra-sonication probe. The composite powder to organic vehicle ratio can be 70:30 by percent weight for all ink formulations. The high-density alumina substrates were acquired from MTI Corporation (USA, CA). The stencil to pattern the thermocouple legs (L-shaped form pattern) can be cut from normal 3M masking tape (Backing: Crepe paper; Adhesive: Synthetic rubber solventless; width: 24 mm; length: 50 m; thickness: 0.10 mm) using a CO₂ laser cutter (BossLaser BOSS-LS 1416). The cutting power can be 60 W with a cutting speed of 60 mm/s. To fabricate the thermocouple pattern, two layers of 3M masking tape were stacked onto each other and pushed together to make a thickness of 0.2 mm. The L-shaped pieces of masking tape were cut by a laser cutter to dimensions of 100 mm and 6 mm. The L-shaped pieces were then placed and pushed down to stick to the electronic grade alumina substrate (120×30 mm) using a rubber blade pushed over the surface to adhere in all locations. Approximately 2 g of undoped LaCrO₃—Al₂O₃ composite ink can be pipetted at the long end of the channel and pushed down the L-shaped channel mold parallel to the channel length using a rubber edge. At the 90° location, the ink can be pushed parallel to the direction of the smaller channel design to fill the whole channel evenly using a rubber blade. Excess material can be pushed up onto the masking tape. The printed electrode or leg can be dried at 70° C. in an oven for 20 min. Two separate layers of tape were stacked and pressed onto one another to make a 0.2-mm thickness. A new L-shaped piece of masking tape can be cut by the laser cutter. The second two-layer stack of tape can be aligned to the other pre-printed L-shapes on the alumina substrate to make a channel between the two L-shaped pieces. Again, about 2 g of undoped LaCrO₃ ink can be pipetted at the long end of the channel, spread and dried in a similar method as the first leg. Finally, a third L-shaped piece of masking tape can be again cut, and the layers were placed onto the previous two layers on the alumina substrate to build a total stack of 3 tapes that were 0.6-mm thick. The same methods were repeated to stencil and dry a third layer.

After drying, masking tapes can be removed and sintered in a tube furnace (Nabertherm RHTH 120/150/18/ furnace, Germany) within a dry air atmosphere using the following heating procedure: 30° C. to 600° C. at 2° C./min, then heated up to 1500° C. at 3° C./min and held for 60 min, then cooled down to 30° C. at 2° C./min. This procedure can be used to print and bond one side (or first leg) of the thermocouple (in this case, the LaCrO₃ (LC) side of the thermocouple). To produce the entire thermocouple, the second leg (the doped LaCrO₃ compositional side) can be replicated as a mirror image of the first leg, with a slight overlap to create a junction between the two legs. The same stencil printing method can be used to produce the second leg, with the only difference being the doped LaCrO₃ ink composition. After stenciling the second leg, overlapping the first LC leg by about 1 to 3 mm, the thermocouple can be sintered in a tube furnace (Nabertherm RHTH 120/150/18/ furnace, Germany) under a dry air atmosphere, using the following heating program: 30° C. to 600° C. at 2° C./min, then heat up to 1500° C. at 3° C./min and hold for 60 min, then cooling down to 30° C. at 2° C./min.

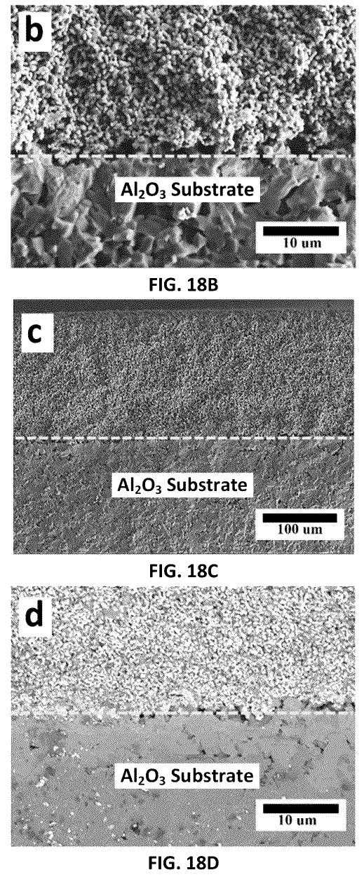

FIGS. 18A-18D show cross-section SEM photographs of two printed conductive legs on an alumina substrate after sintering for 2 hrs at 1500° C.; FIG. 18A and FIG. 18B show the cross section of an LCC30 printed thick-film on an alumina substrate and FIG. 18C and FIG. 18D show the cross section of a LCC30-Al₂O₃ composite printed thick-film on an alumina substrate. Better sinterability between the substrate and the conductive phase can be achieved by the LCC30-Al₂O₃ thick-film compared to the LCC30 thick-film. FIG. 1 shows a magnified image of the LCC30 printed legs on the fabricated thermocouple, highlighting the challenges of chromium diffusion and redeposition without the addition of a refractory oxide to form a ceramic composite.

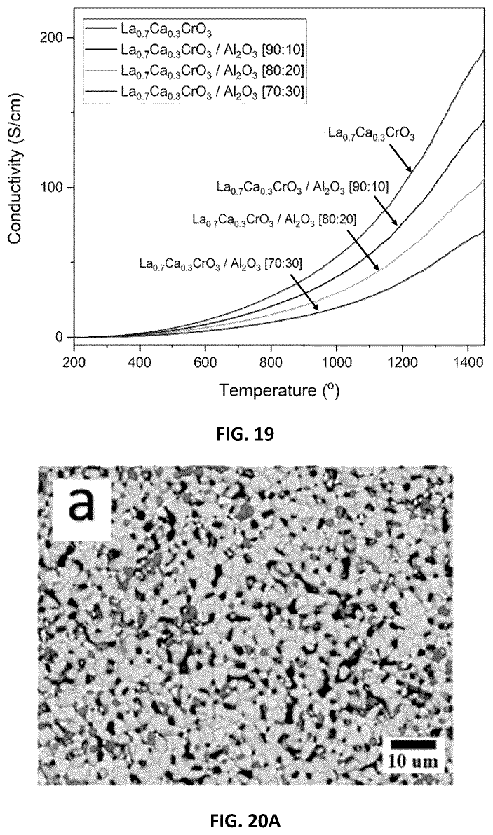

To complement the understanding of the thermoelectrical properties of LCC3-Al₂O₃ composites, electrical conductivity measurements as a function of temperature up to 1500° C. were performed. FIG. 19 shows the experimental temperature dependence of the electrical conductivity of LCC30 and different LCC30-Al₂O₃ composites under an air atmosphere. FIG. 19 shows LCC30 had an exponential correlation between electrical conductivity and temperature up to 1500° C. FIG. 19 also illustrates how the increment of Al₂O₃ from 10 to 30 vol % in the LCC30-Al₂O₃ composite decreased the magnitude of electrical conductivity compared to LCC30 over the same temperature range. This decrement can be related to Al₂O₃ and aluminate insulator phase grain formation and the evolution of 3-3 connectivity in the composite microstructure. According to XRD and XPS analysis, after sintering the composites, new phases of LaAlO₃ and Ca₂Al₂O₅ were formed. Grains of such phases can act as resistors within the microstructure of the composite mixture.

### Example 6: Microstructure of Composite Thermocouples

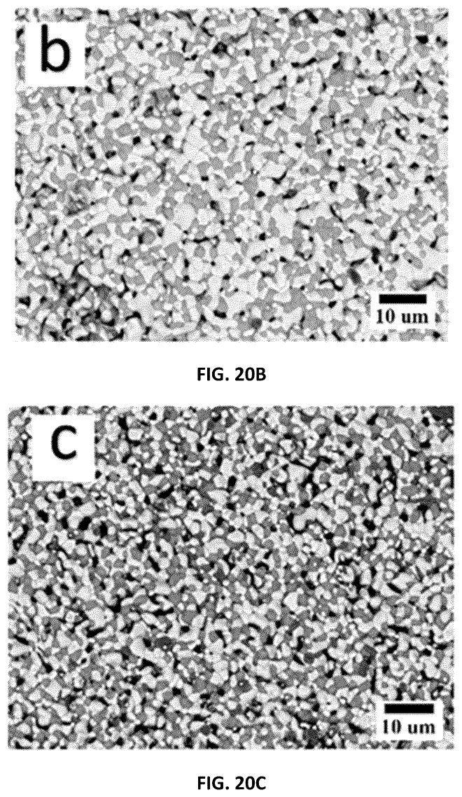

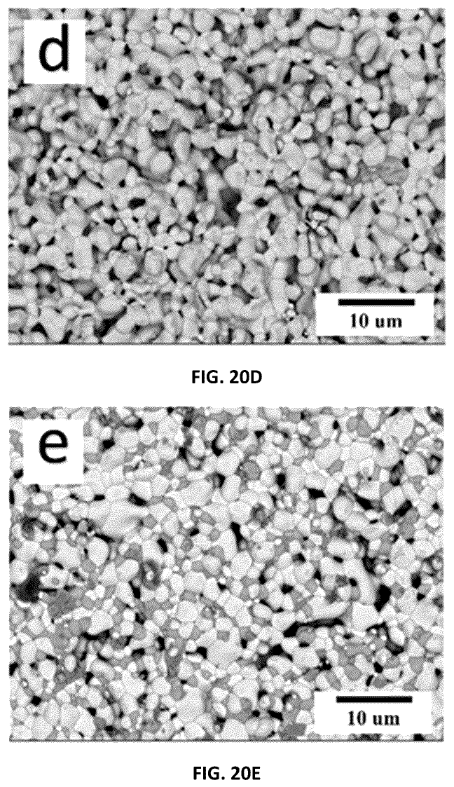

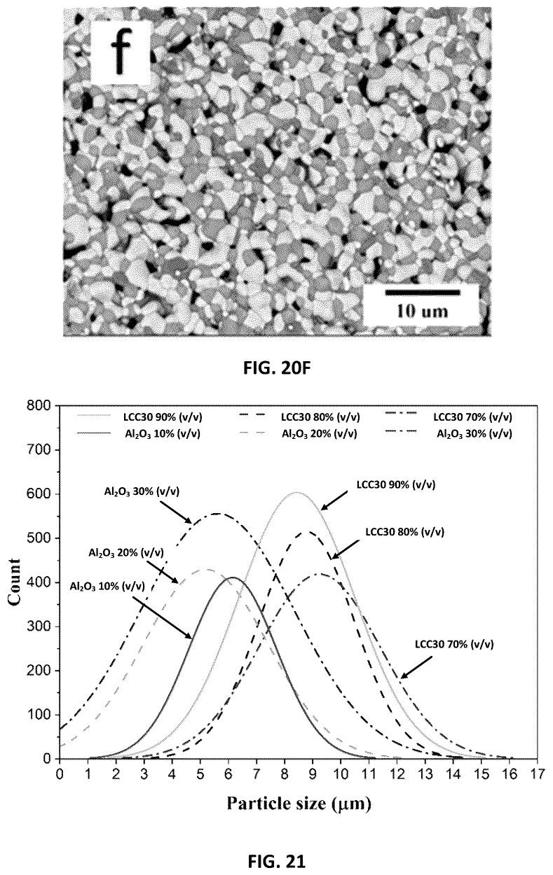

SEM and EDS chemical analysis were completed to illustrate the effect of Al₂O₃ content on the microstructure and phase distribution in sintered thermocouple legs based on LCC30-Al₂O₃ composites. FIGS. 20A-20F show backscattered SEM micrographs of the surfaces of sintered thermocouple legs fabricated with LCC30-Al₂O₃ ceramic composites. The bright regions in the backscattered SEM micrographs correspond to the LCC30 phase, while dark regions represent the Al₂O₃/aluminate phases. FIG. 21 shows the particle size distribution for LCC30 and aluminum oxides as a function of volume percent content in the different composite formulations used in the fabrication of the thermocouple. In FIG. 20A and FIG. 20D, the LCC30-Al₂O₃ [90-10] microstructure can be observed. This composite showed a higher content of LCC30 phase relative to aluminum oxide phases, which were distributed individually (single spots) between the LCC30 granular microstructure. However, by increasing Al₂O₃ content from 20 to 30 vol %, the aluminum oxide grain distribution increased proportionally throughout the microstructure and exhibiting interconnected grains unlike 10 vol % of Al₂O₃ as shown in FIG. 20B, FIG. 20C, FIG. 20E and FIG. 20F. Al₂O₃ increase did not have a general effect on the porosity of the sintered composites. According to FIG. 21, the aluminum oxide grains presented an average size between 5.6 and 6.2 μm, while LCC30 grains had an observed average size between 8.4 and 9.3 μm.

The level of connectivity of the conductive phase in the ceramic composite (LCC30) altered its thermoelectric properties as well as its chemical and thermoelectrical stability. For a two-phase material such as LCC30-Al₂O₃, a 3-3 composite, which designates an interconnected mixture of the two phases, appears like a sponge-like structure where the solid material is connected in three dimensions, as well as the 3-D connectivity of the porosity or void space of the sponge-like structure. Depending on the volumetric ratio of LCC30 and Al₂O₃ (and the particle size ratio of each of these constituents), a 3-0 composite (at typically ≤10 vol % Al₂O₃ content) or a 3-3 composite (at typically >10 vol % Al₂O₃ content) formed. No connectivity can be observed between Al₂O₃/aluminates grains at 10 vol % of Al₂O₃, indicating a 3-0 composite formation as shown in FIG. 20A. However, the connectivity of the grains can be apparent for 20 and 30 vol % Al₂O₃, indicating 3-3 composite formation (see FIG. 20B and FIG. 20C). Complementary backscattered SEM pictures and EDS atomic mapping illustrated Al₂O₃, LaAlO₃, and Ca₂Al₂O₅ phases co-existed within single grains.

### Example 7: Thermoelectrical Characterization and Testing of the Full Ceramic Composite Thermocouples

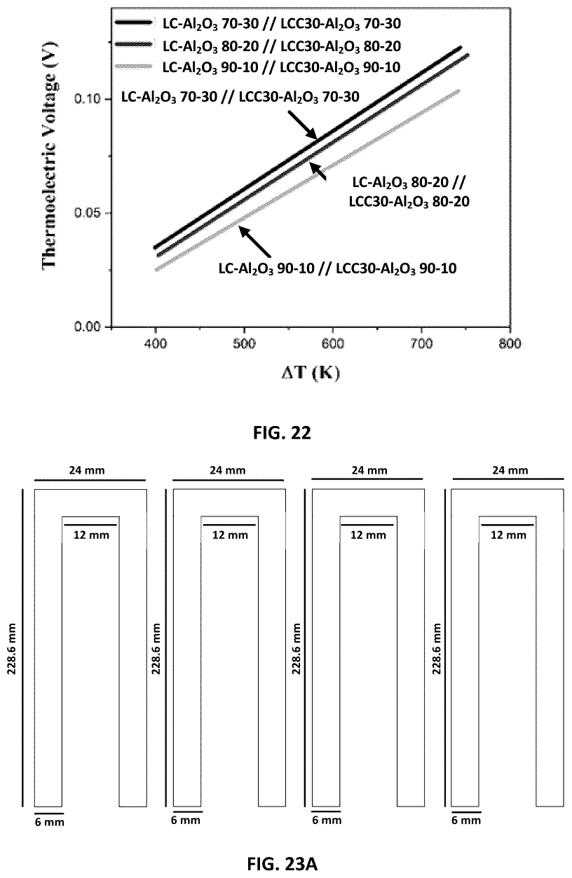

FIG. 22 shows a thermoelectric voltage as a function of temperature difference for a LCC30-Al₂O₃// LC-Al₂O₃ ceramic composite thermocouple. By increasing Al₂O₃ content, an increase in both the thermoelectric potential and the magnitude of the slope can be observed. This shows that increasing Al₂O₃ content increased thermoelectric potential due to the formation of secondary phases of insulating oxides such as LaAlO₃, Ca₂Al₂O₅ and Al₂O₃. FIGS. 20A-20F show that there can be a systematic increase of Al₂O₃/aluminate grains (represented as dark grey grains) in the microstructure of the composites. These increases enhance chromium diffusion within the alumina phase and formation of insulating oxide phases, producing a decrease in LCC-Al₂O₃ composites electrical conductivity, as shown in FIG. 19.

Table 7 lists experimental Seebeck coefficients for three LCC30-Al₂O₃//LC-Al₂O₃ ceramic composites thermocouples, which shows the Seebeck coefficient increasing depending on the amount of Al₂O₃ content. The formation and distribution of Al₂O₃ grains throughout the composite microstructure increased electrical resistivity. FIG. 22 illustrates that thermocouples fabricated with complete composite structures exhibit an augmented thermoelectric voltage output. This increase is notable as Al₂O₃ content rises from 10 to 30 vol %. The response demonstrates that the percentage of refractory oxide used does not override the p-type semiconductor properties of LC and LCC30. The formation of secondary compounds produced during the sintering and heating process increased the electrical resistivity of these materials as well as the intrinsic Seebeck coefficients. In comparing the ceramic composite values with the the Seebeck coefficient of the LCC30//LC thermocouple which can be about 222 μV/K, it can be concluded that the chemical reaction and cation interdiffusion between both phases at the junction produces this modification and alteration of the thermoelectrical properties.

TABLE 7
Experimental Seebeck Coefficients from Characterization
of Thick-Film Thermocouples

| Thermocouple | A (μV/K) |
|---|---|
| LCC30 - Al2O3 [90-10] // LC - Al2O3 [90-10] | 230.34 |
| LCC30 - Al2O3 [80-20] // LC - Al2O3 [80-20] | 252.56 |
| LCC30 - Al2O3 [70-30] // LC - Al2O3 [70-30] | 252.21 |

### Example 8: LaCrO₃-Based Ceramic Composite Thermocouples Using Sacrificial Substrate Methods

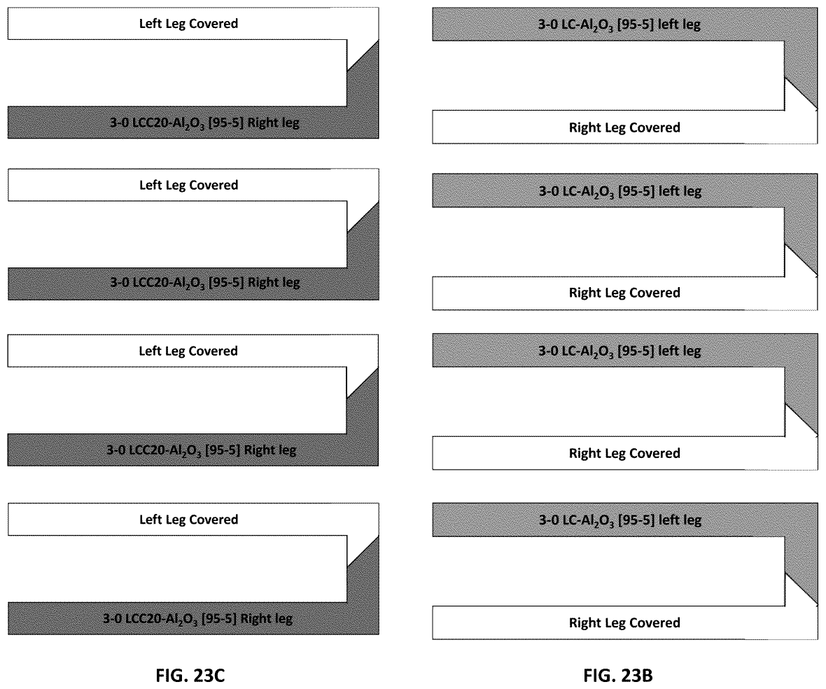

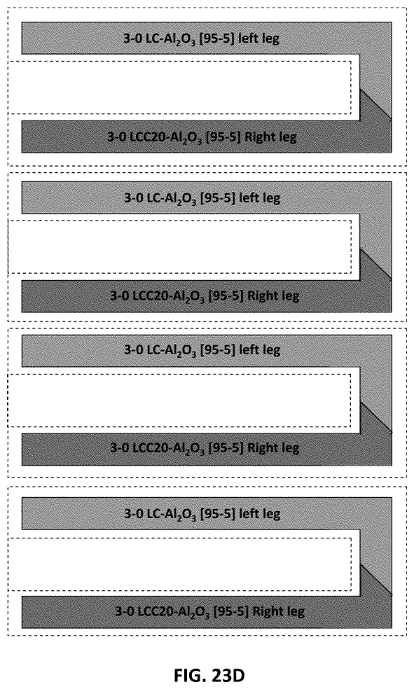

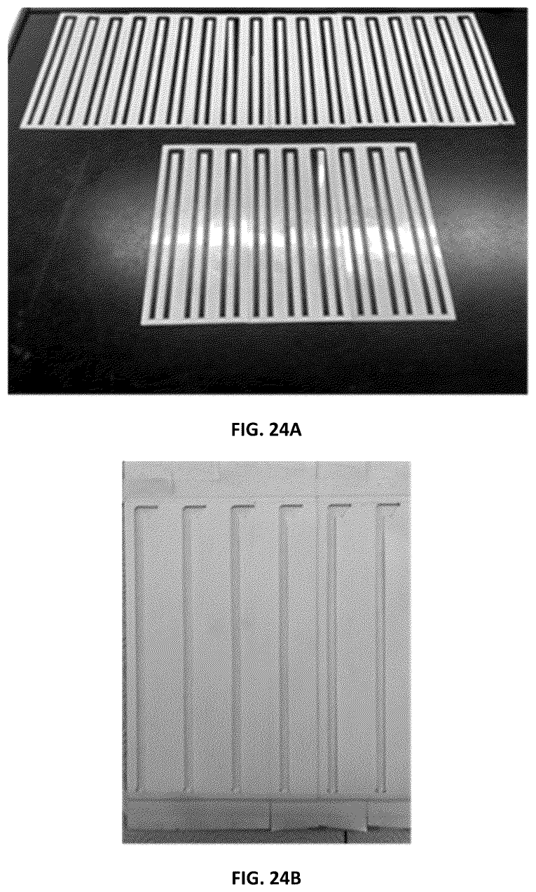

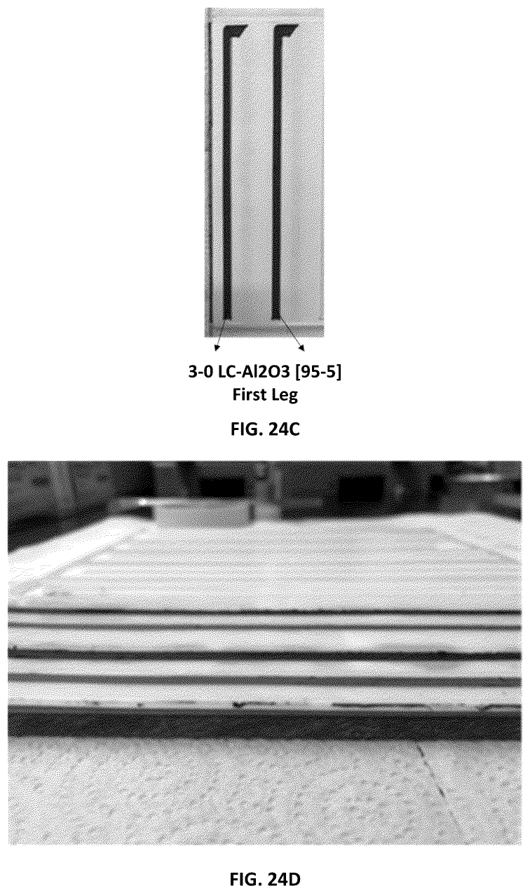

Undoped and doped LaCrO₃—Al₂O₃ composite inks for stencil printing were prepared by mixing 66 g of composite powder with about 38.7 g of an ethanol-xylene mixture (50-50% by weight) and 1.4 grams of a fish oil solution in xylene for about 4 hrs on a US Stoneware 755RMV ball rolling system. Finally, 3 g of Plasticizer UCON50HB2000 (Polyalkylene Glycol), 3 g of Plasticizer S-160 (butyl benzyl phthalate), and 6 g of Polyvinyl butyral (PVB) were added to the previous mixture and mixed for about 8 hrs on a US Stoneware 755RMV ball rolling system. The stencil to pattern the thermocouple legs (L-shaped pattern) can be cut from high density, 0.35-mm thick plastic sheets using a CO₂ laser cutter (BossLaser BOSS-LS 1416). The cutting power can be 60 W with a cutting speed of 60 mm/s. Four double L-shaped pieces of plastic were cut by a laser cutter to 228.6 mm (length) and 6 mm (width) dimensions (see FIGS. 23A-23D). The double L-shaped stencil can then be placed and pushed down to stick on dissolvable 120×30 mm filter paper using a rubber blade pushed over the surface to adhere in all locations. Approximately 2 g of 3-0 LC-Al₂O₃ [95-5] composite ink can be pipetted at the long end of the left leg channel (the right channel can be covered with paper) and pushed down parallel to the channel length using a rubber edge. At the ninety-degree location, the ink can be pushed parallel to the direction of the smaller channel design to fill the whole channel evenly using a rubber blade. This procedure can be completed for all the other three left legs channels. The printed electrodes or thermocouple legs were dried at room temperature for about 8 hrs and gently covered with paper. Two grams of 3-0 LCC20-Al₂O₃ [95-5] composite ink can then be pipetted along the edge of the right channel and printed and dried in the same way as discussed previously (see FIGS. 24A-24D). After drying, the plastic stencils were manually removed and each single printed thermocouple preform can be cut using the laser cutter, casted, and embedded into a high alumina cement as follows: A three-part mold can be fabricated from polylactic acid (PLA) with dimensions of 9×2×2-in. An oil release agent can be applied to the inside of the mold pieces, and the base and middle frame were assembled for casting. The high alumina cement can be fabricated using 280 grams of high alumina cement mixed with 12% by weight deionized water). The high alumina cement can be poured into the mold to form a bottom layer or the first part of an outer layer. While the refractory can be wet and setting, the stencil printed thermocouple preform can be dropped and centered on the surface of the first part of an outer layer to collectively form a base layer. Finally, using the same refractory casting technique as before, a top layer or the second part of an outer can be added to the mold and the top layer refractory material can be cast to encase the base layer. The cast and embedded thermocouple can be dried in open air at room temperature for 48 hrs, and subsequently dried in a conventional oven at 70° C. for 24 hours. Finally, it can be sintered in a tube furnace (Nabertherm RHTH 120/150/18/ furnace, Germany) under a dry air atmosphere, using the following heating program: 30° C. to 600° C. at 2° C./min, then heated up to 1500° C. at 3° C./min and held for 60 min, then cooling down to 30° C. at 2° C./min. The electrical contacts to the thermocouples for the related characterization were made using platinum (Pt) made paste and wires.

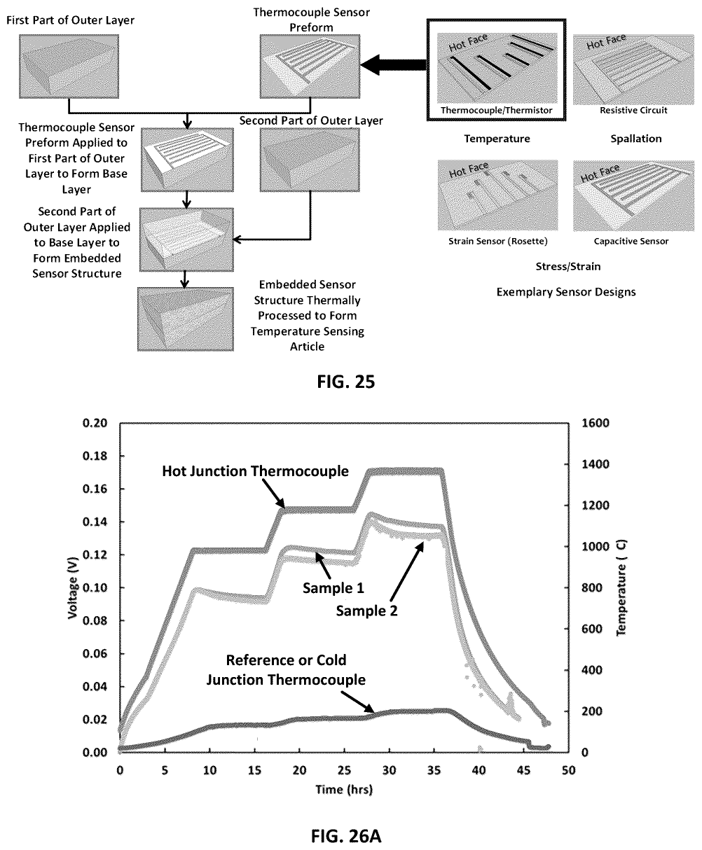

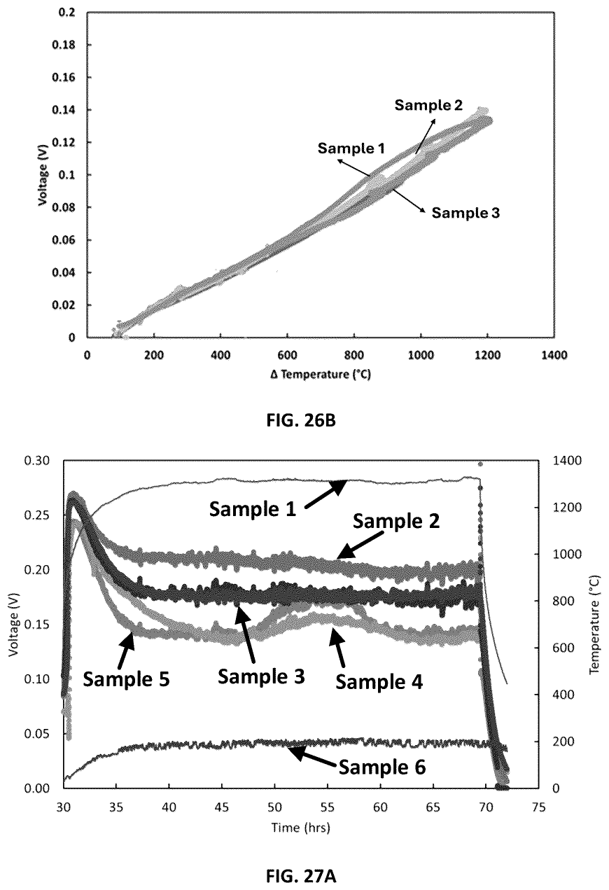

Additional performance results on thermocouple devices embedded within refractory cement can be obtained. Thermocouples were fabricated by a stencil printing method and embedded into 1.0×0.5×6.0-in refractory brick. These bricks were cast, sintered, and tested in a gas-fired kiln. The stencil thickness evaluated can be 350 μm. The stencils were adhered onto filter paper and the filter paper with dried, green sensing material can be embedded into the brick during casting process. The bricks were sintered at 1500° C. With the 350-μm thick stencil, only one layer of sensing materials can be applied for each leg of the thermocouple. FIG. 25 shows a general overview of this method utilizing only one inner layer for the sensor legs which becomes embedded within the outer refractory brick layer upon sintering to form a monolithic structure. FIG. 26A shows thermoelectric voltage over time for nearly two days of operation at high temperature. FIG. 26B shows the data for replicates of the thermoelectric voltage output of the embedded thermocouples as a function of time and temperature difference. The sensors showed a consistent and reproducible output in all cases with not significant outlier results. FIG. 26A and FIG. 26B show similar thermoelectric voltage as a function of time for additional thermocouple devices located in various locations within the gas-fired kiln.

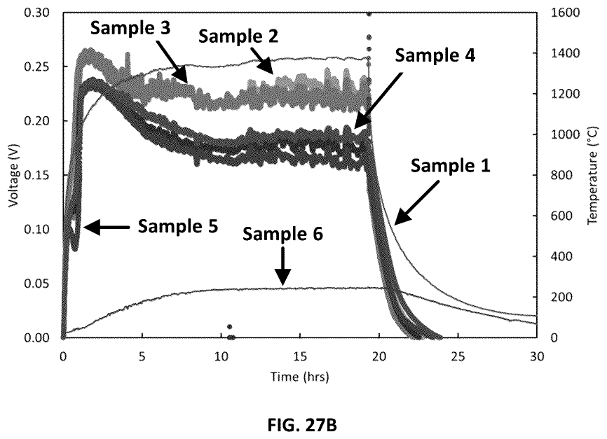

Additional tests were performed with an alternative stenciling ink formulation used to deposit sensor materials. Thermocouple legs can be deposited onto Waltman filter paper number 42 using a stencil acting as the sacrificial substrate, for example. The deposited paper can then placed in a brick during casting of the refractory. While the brick is sintered, the paper disintegrates or dissolves, leaving behind a sensor embedded within the fired brick. Two additional sacrificial substrates were evaluated: coarse filter paper (30-50 mm pore size) and dissolvable paper alongside the Waltman 42 filter paper (2.5 mm pore size). Six sensors were fabricated and tested for each substrate. FIG. 27A and FIG. 27B show voltage and temperature profiles over time for two batches (six samples each) tested up to about 1400° C. for each sacrificial substrate employed. FIG. 27A used a dissolvable paper as the sacrificial substrate, and FIG. 27B used a coarse filter paper. The coarse filter paper demonstrated the least spread in terms voltage generated between the two sensor set-ups.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

What is claimed:

1. A thermocouple device comprising,
at least one inner layer embedded within an outer layer;
wherein the outer layer is comprised of at least one phase of a first refractory oxide;
wherein the at least one inner layer is comprised of a first leg and a second leg;
wherein the first leg is comprised of a first composite mixture of at least one phase of a first undoped or doped LaCrO₃ in contact with at least one phase of a second refractory oxide;
wherein the second leg is comprised of a second composite mixture of at least one phase of a second undoped or doped LaCrO₃ in contact with at least one phase of a third refractory oxide;
wherein the first leg and the second leg are in electrical contact with each other to form a junction;
wherein the first composite mixture and the second composite mixture are different compositions; and
wherein a thermoelectric voltage is generated between the first leg and the second leg.

2. The thermocouple device of claim 1, wherein the at least one inner layer has a porosity of about 0 to 80%.

3. The thermocouple device of claim 1, wherein the at least one phase of the first refractory oxide comprises Al₂O₃, Cr₂O₃, ZrO₂, SiO₂, MgO, CaO, Fe₂O₃, P₂O₅, or combinations thereof.

4. The thermocouple device of claim 1, wherein the at least one phase of the second refractory oxide comprises Al₂O₃, Cr₂O₃, ZrO₂, SiO₂, MgO, CaO, Fe₂O₃, P₂O₅, or combinations thereof.

5. The thermocouple device of claim 1, wherein the at least one phase of the third refractory oxide is comprised of Al₂O₃, Cr₂O₃, ZrO₂, SiO₂, MgO, CaO, Fe₂O₃, P₂O₅, or combinations thereof.

6. The thermocouple device of claim 1, wherein the at least one phase of a first refractory oxide, the at least one phase of the second refractory oxide, and the at least one phase of the third refractory oxide comprise Al₂O₃, Cr₂O₃, or combinations thereof.

7. The thermocouple device of claim 1, wherein the at least one phase of a first refractory oxide comprises a high alumina cement.

8. The thermocouple device of claim 1, wherein the at least one phase of the first undoped or doped LaCrO₃ or the at least one phase of the second undoped or doped LaCrO₃ comprise a composition represented by the formula (La₁₋ₓAₓ)(Cr_{1-y}B_{y})O₃;
wherein A=Ca, Sr, Ba, or Y and B=Nb, Ti, Zr, Mn, Fe, Co, Cu, Ni, Mn, Zn, Al, Gd, Nd, or Sm; and
wherein 0≤x≤0.5 and 0≤y≤0.5.

9. The thermocouple device of claim 1, wherein the at least one phase of the first undoped or doped LaCrO₃ or the at least one phase of the second undoped or doped LaCrO₃ comprise a composition represented by the formula (La₁₋ₓAₓ)CrO₃;
wherein A=Ca or Sr; and
wherein 0≤x≤0.3.

10. The thermocouple device of claim 1, wherein the at least one phase of the first undoped or doped LaCrO₃ or the at least one phase of the second undoped or doped LaCrO₃ comprise a composition represented by the formula (La₁₋ₓAₓ)CrO₃;
wherein A=Ca; and
wherein x=0.3.

11. The thermocouple device of claim 1,
wherein the at least one phase of a first undoped or doped LaCrO₃ and the at least one phase of a second refractory oxide are present in the first composite mixture in a volumetric ratio ranging from about 70:30 to about 99:1, respectively; and
wherein the at least one phase of a second undoped or doped LaCrO₃ and the at least one phase of a third refractory oxide are present in the second composite mixture in a volumetric ratio ranging from about 70:30 to about 99:1, respectively.

12. The thermocouple device of claim 1, wherein three-dimensional microstructure connectivity is present in the first composite mixture, the second composite mixture, or combination thereof.

13. The thermocouple device of claim 1, wherein three-dimensional microstructure connectivity is present in the at least one phase of the first undoped or doped LaCrO₃, the at least one phase of the second undoped or doped LaCrO₃, or combination thereof.

14. The thermocouple device of claim 1,
wherein the at least one phase of the first undoped LaCrO₃ and the at least one phase of the second refractory oxide are present in the first composite mixture in a volumetric ratio ranging from about 70:30 to about 99:1, respectively;
wherein the at least one phase of the second doped LaCrO₃ represented by the formula La_{0.7}Ca_{0.3}CrO₃ and the at least one phase of the third refractory oxide are present in the second composite mixture in a volumetric ratio ranging from about 70:30 to about 99:1, respectively; and
wherein the at least one phase of the first refractory oxide, the at least one phase of a second refractory oxide, and the at least one phase of the third refractory oxide are comprised of Al₂O₃, Cr₂O₃, or combination thereof.

15. The thermocouple device of claim 1, wherein the at least one inner layer and the outer layer form a monolithic structure.

16. The thermocouple device of claim 1,
wherein the at least one inner layer comprises a plurality of inner layers; and
wherein the plurality of inner layers has a functionally graded microstructure such that the volumetric ratio of refractory oxide within each layer increases from an inner most layer to the outer layer.

17. The thermocouple device of claim 1, wherein the stable temperature sensing range of the thermocouple device is from about 100 to about 1500° C.

18. The thermocouple device of claim 1, wherein the thermocouple device has an effective Seebeck coefficient of about 230 to about 252 μV per K.

19. A temperature sensing article comprising:
at least one inner layer embedded within an outer layer;
wherein the at least one inner layer is comprised of a first leg and a second leg;
wherein the first leg is comprised of a first composite mixture of an undoped or doped LaCrO₃ in contact with a refractory oxide in a volumetric ratio ranging from about 70:30 to about 95:5, respectively;
wherein the second leg is comprised of a second composite mixture of an undoped or doped LaCrO₃ in contact with a refractory oxide in a volumetric ratio ranging from about 70:30 to about 95:5, respectively;
wherein the first leg and the second leg are in electrical contact with each other to form a junction;
wherein the first composite mixture and the second composite mixture are different compositions such that a thermoelectric voltage is generated between the first leg and the second leg;
wherein the doped LaCrO₃ is represented by the formula La_{0.7}Ca_{0.3}CrO₃;
wherein the outer layer is comprised of a refractory oxide;
wherein the refractory oxide is comprised of Al₂O₃, Cr₂O₃, ZrO₂, SiO₂, MgO, CaO, Fe₂O₃, P₂O₅, or combinations thereof; and
wherein the temperature sensing article is a monolithic structure.

20. A thermocouple sensor preform comprising:
a first leg;
a second leg;
a sacrificial substrate;
wherein the first leg is comprised of a first composite mixture of an undoped or doped LaCrO₃ in contact with a refractory oxide in a volumetric ratio ranging from about 70:30 to about 95:5, respectively;
wherein the second leg is comprised of a second composite mixture of an undoped or doped LaCrO₃ in contact with a refractory oxide in a volumetric ratio ranging from about 70:30 to about 95:5, respectively;
wherein the first leg and the second leg are disposed on the sacrificial substrate and are in electrical contact with each other to form a junction;
wherein the first composite mixture and the second composite mixture are different compositions such that a thermoelectric voltage is generated between the first leg and the second leg;
wherein the doped LaCrO₃ is represented by the formula La_{0.7}Ca_{0.3}CrO₃;
wherein the refractory oxide is comprised of Al₂O₃, Cr₂O₃, ZrO₂, SiO₂, MgO, CaO, Fe₂O₃, P₂O₅, or combinations thereof; and
wherein the sacrificial substrate disintegrates at a temperature lower than the sintering temperature of the first composite mixture and the second composite mixture.
